(19) United States
(12) Patent Application Publication
(10) Pub. No.: US 2026/0235952 A1
(43) Pub. Date: Aug. 13, 2026

(54) COPOLYMER, POSITIVE RESIST COMPOSITION, AND METHOD OF FORMING RESIST PATTERN

(71) Applicant: ZEON CORPORATION, Chiyoda-ku, Tokyo (JP)

(72) Inventors: Akiya KAWAUE, Chiyoda-ku, Tokyo (JP); Masaya UMEDA, Chiyoda-ku, Tokyo (JP)

(73) Assignee: ZEON CORPORATION, Chiyoda-ku, Tokyo (JP)

(21) Appl. No.: 19/149,849

(22) PCT Filed: Mar. 18, 2024
(86) PCT No.: PCT/JP2024/010605

§ 371 Date: Jul. 22, 2025

(30) Foreign Application Priority Data
Mar. 30, 2023 (JP) 2023-056621

(51) Int. Cl. G03F 7/039; C08F 222/18; G03F 7/32

(52) U.S. Cl. CPC G03F 7/039; C08F 222/18; G03F 7/325

(57) ABSTRACT

Provided are a copolymer and a positive resist composition that have a wide exposure margin and that can form a resist pattern having a good shape. The copolymer includes a monomer unit (I) represented by formula (I), shown below, a monomer unit (II) represented by formula (II), shown below, and a monomer unit (III) represented by formula (III), shown below. In the formulae, R¹ to R¹⁴ are specific groups and p is an integer of not less than 0 and not more than 5.

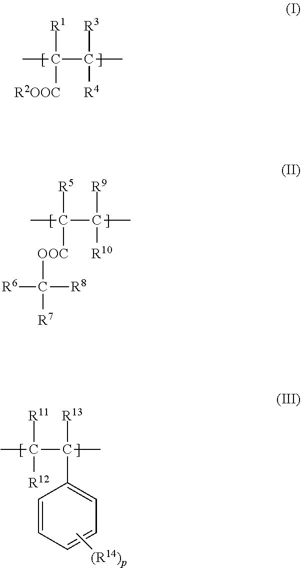

### TECHNICAL FIELD

The present disclosure relates to a copolymer, a positive resist composition, and a method of forming a resist pattern.

### BACKGROUND

Polymers that display increased solubility in a developer after undergoing main chain scission through irradiation with ionizing radiation, such as an electron beam or extreme ultraviolet radiation (EUV), or non-ionizing radiation, inclusive of short-wavelength light such as ultraviolet radiation, are conventionally used as main chain scission-type positive resists in fields such as semiconductor production. (Hereinafter, the term “ionizing radiation or the like” is used to refer collectively to ionizing radiation and non-ionizing radiation.)

As one specific example, Patent Literature (PTL) 1 discloses a resist that contains a copolymer including a 1-phenyl-1-trifluoromethyl-2,2,2-trifluoroethyl α-chloroacrylate unit and a 4-methyl-α-methyl styrene unit or an α-methylstyrene unit and having a weight-average molecular weight of more than 100,000 as a main chain scission-type positive resist that can efficiently form a fine resist pattern with high resolution.

### CITATION LIST

### Patent Literature

PTL 1: WO2022/070928A1

### SUMMARY

### Technical Problem

In recent years, demand for high integration of semiconductor integrated circuits, for example, has led to demand for main chain scission-type positive resists to have a wide exposure margin (i.e., to have high tolerance with respect to the magnitude of exposure dose in an exposure step). There is also demand for main chain scission-type positive resists to impart excellent shape to a resist pattern that has been formed through an exposure step and development treatment using a developer (development step).

However, a positive resist of the conventional technique described above leaves room for improvement in terms of widening the exposure margin while also imparting a good shape to a resist pattern.

Accordingly, one object of the present disclosure is to provide a copolymer and a positive resist composition that have a wide exposure margin and that can form a resist pattern having a good shape.

Another object of the present disclosure is to provide a method of forming a resist pattern that has a wide exposure margin and that can form a resist pattern having a good shape.

The inventors conducted diligent investigation to achieve the objects set forth above. The inventors made a new discovery that by using a copolymer including three types of specific monomer units, it is possible to widen the exposure margin of a resist while also forming a resist pattern having a good shape, and, in this manner, completed the present disclosure.

Specifically, with the aim of advantageously solving the problem set forth above, [1] a presently disclosed copolymer comprises:
a monomer unit (I) represented by formula (I), shown below:

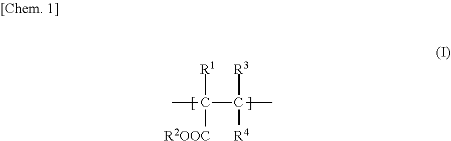

where, in formula (I), R¹ is a halogen atom or a halogen atom-substituted alkyl group, R² is a fluorine atom-containing organic group, and R³ and R⁴ are each a hydrogen atom, a halogen atom, an unsubstituted alkyl group, or a halogen atom-substituted alkyl group and may be the same as or different from each other;
a monomer unit (II) represented by formula (II), shown below:

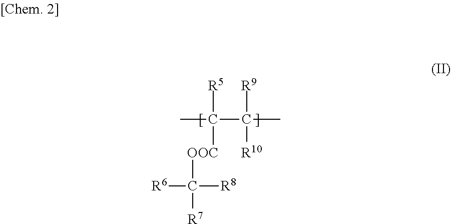

where, in formula (II), R⁵ is a halogen atom or a halogen atom-substituted alkyl group, R⁶, R⁷, and R⁸ are each a hydrogen atom or an optionally substituted aliphatic group that does not include a fluorine atom and may be the same as or different from one another, R⁶, R⁷, and R⁸ may form a ring structure with a carbon atom that is bonded thereto, and R⁹ and R¹⁰ are each a hydrogen atom or an unsubstituted alkyl group and may be the same as or different from each other; and
a monomer unit (III) represented by formula (III), shown below:

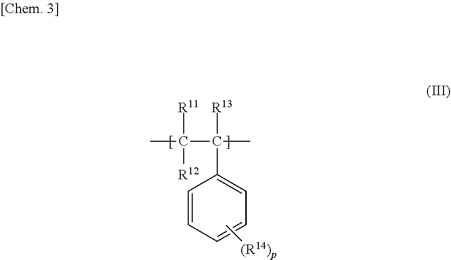

where, in formula (III), R¹¹ and R¹² are each a hydrogen atom or an unsubstituted alkyl group and may be the same as or different from each other, R¹³ is an optionally substituted alkyl group, R¹⁴ is a halogen atom or an organic group, and p is an integer of not less than 0 and not more than 5.

By using a copolymer that includes the specific monomer units (I) to (III) set forth above in this manner, it is possible to increase the exposure margin of an obtained resist while also forming a resist pattern having a good shape.

[2] In the copolymer according to the foregoing [1], it is preferable that R² is a group represented by L-Ar, where L is a fluorine atom-containing divalent linking group, and Ar is an optionally substituted aromatic ring group. When R² is a group having the specific structure set forth above in this manner, sensitivity of the copolymer to ionizing radiation or the like can be improved.

[3] In the copolymer according to the foregoing [1] or [2], it is preferable that R⁶, R⁷, and R⁸ are each a hydrogen atom or an optionally substituted aliphatic group having a carbon number of not less than 1 and not more than 10 that does not include a fluorine atom. When R⁶, R⁷, and R⁸ are each a hydrogen atom or the specific aliphatic group set forth above in this manner, the exposure margin can be even further widened while also forming a resist pattern having an even better shape.

[4] In the copolymer according to any one of the foregoing [1] to [3], it is preferable that a proportion constituted by the monomer unit (II) is less than 30 mol %. When the proportion constituted by the monomer unit (II) in the copolymer is less than the upper limit set forth above in this manner, the exposure margin can be even further widened while also forming a resist pattern having an even better shape.

The proportion constituted by a monomer unit in a copolymer referred to in the present disclosure can be measured by a method described in the EXAMPLES section.

Moreover, with the aim of advantageously solving the problem set forth above, [5] a presently disclosed positive resist composition comprises: the copolymer according to any one of the foregoing [1] to [4]; and a solvent. With the positive resist composition set forth above, the exposure margin can be even further widened while also forming a resist pattern having an even better shape.

Furthermore, with the aim of advantageously solving the problem set forth above, [6] a presently disclosed method of forming a resist pattern comprises: forming a resist film using the positive resist composition according to the foregoing [5]; exposing the resist film; and developing the resist film that has been exposed. Through the method of forming a resist pattern set forth above, it is possible to form a resist pattern having a good shape with a wide exposure margin.

[7] In the method of forming a resist pattern according to the foregoing [6], it is preferable that the developing is performed using an alcohol solvent. When the developing is performed using an alcohol solvent, a resist pattern having an even better shape can be formed.

### Advantageous Effect

According to the present disclosure, it is possible to provide a copolymer and a positive resist composition that have a wide exposure margin and that can form a resist pattern having a good shape.

Moreover, according to the present disclosure, it is possible to provide a method of forming a resist pattern that has a wide exposure margin and that can form a resist pattern having a good shape.

### DETAILED DESCRIPTION

The following provides a detailed description of embodiments of the present disclosure.

The presently disclosed copolymer can be used to produce a main chain scission-type positive resist composition that undergoes main chain scission to lower molecular weight through ionizing radiation or the like, for example, and can suitably be used to produce the presently disclosed positive resist composition. The presently disclosed positive resist composition contains the presently disclosed copolymer and can suitably be used in the presently disclosed method of forming a resist pattern, for example. Moreover, the presently disclosed method of forming a resist pattern can suitably be used in formation of a resist pattern in a production process of a printed board such as a build-up board, a semiconductor, a photomask, or a mold, for example.

### (Copolymer)

The presently disclosed copolymer is a copolymer that includes:
a monomer unit (I) represented by formula (I), shown below:

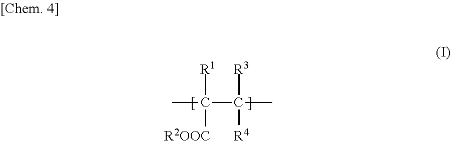

(in formula (I), R¹ is a halogen atom or a halogen atom-substituted alkyl group, R² is a fluorine atom-containing organic group, and R³ and R⁴ are each a hydrogen atom, a halogen atom, an unsubstituted alkyl group, or a halogen atom-substituted alkyl group and may be the same as or different from each other);
a monomer unit (II) represented by formula (II), shown below:

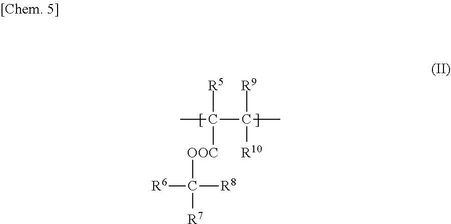

(in formula (II), R⁵ is a halogen atom or a halogen atom-substituted alkyl group, R⁶, R⁷, and R⁸ are each a hydrogen atom or an optionally substituted aliphatic group that does not include a fluorine atom and may be the same as or different from one another, R⁶, R⁷, and R⁸ may form a ring structure with a carbon atom that is bonded thereto, and R⁹ and R¹⁰ are each a hydrogen atom or an unsubstituted alkyl group and may be the same as or different from each other); and
a monomer unit (III) represented by formula (III), shown below:

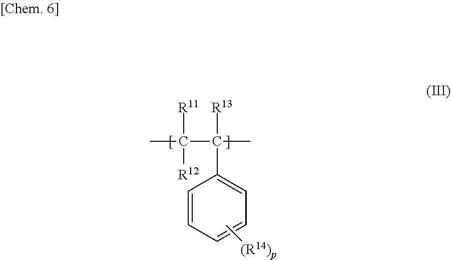

(in formula (III), R¹¹ and R¹² are each a hydrogen atom or an unsubstituted alkyl group and may be the same as or different from each other, R¹³ is an optionally substituted alkyl group, R¹⁴ is a halogen atom or an organic group, and p is an integer of not less than 0 and not more than 5).

Although the presently disclosed copolymer may include other monomer units besides the monomer units (I) to (III), the proportion constituted by the monomer units (I) to (III) among all constituent monomer units (100 mol %) of the copolymer is, in total, preferably 90 mol % or more, and more preferably 100 mol % (i.e., it is more preferable that the copolymer is composed of the monomer units (I) to (III)).

The presently disclosed copolymer may be a random copolymer, a block copolymer, an alternating terpolymer, or the like without any specific limitations so long as it includes the monomer units (I) to (III). Note that the alternating terpolymer referred to in the present disclosure is an alternating copolymer in which a monomer unit (I) or a monomer unit (II) is copolymerized between monomer units (III). Specifically, as a schematic illustration, the various monomer units bonded in are a manner such as “-(III)-(I)-(III)-(II)-(III)-”.

As a result of the presently disclosed copolymer including the specific monomer units (I) to (III), irradiation with ionizing radiation or the like causes only copolymer in a section that has been irradiated to undergo good main chain scission to lower molecular weight. Moreover, components resulting from this reduction of molecular weight dissolve well in a developer. Although it is not necessarily certain why the exposure margin of an obtained resist can be widened while also forming a resist pattern having a good shape as a result of the presently disclosed copolymer including the specific monomer units (I) to (III), the reason for this is presumed to be as follows. Specifically, it is presumed that the inclusion of the monomer unit (I), the monomer unit (II), and the monomer unit (III), which differ in terms of solubility in a developer, makes it possible to control solubility in a developer and thereby widen the exposure margin while also forming a resist pattern having a good shape.

### <Monomer Unit (I)>

The monomer unit (I) that is included in the presently disclosed copolymer is a monomer unit that is derived from a monomer (a) represented by the following formula (a).

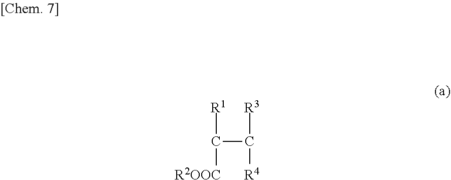

(In formula (a), R¹ to R⁴ have the same meaning as in formula (I).)

The halogen atom that can constitute R¹, R³, and R⁴ in formula (I) and formula (a) may be a chlorine atom, a fluorine atom, a bromine atom, or an iodine atom without any specific limitations. Moreover, the halogen atom-substituted alkyl group that can constitute R¹, R³, and R⁴ in formula (I) and formula (a) may be a group having a structure resulting from a portion of or all of the hydrogen atoms in an alkyl group being replaced by any of the above-described halogen atoms without any specific limitations.

The unsubstituted alkyl group that can constitute R³ and R⁴ in formula (I) and formula (a) may be an unsubstituted alkyl group having a carbon number of not less than 1 and not more than 10 without any specific limitations. In particular, the unsubstituted alkyl group that can constitute R³ and R⁴ is preferably a methyl group or an ethyl group.

From a viewpoint of improving main chain scission properties of the copolymer upon irradiation with exposure light and increasing efficiency of resist pattern formation, R¹ in formula (I) and formula (a) is preferably a chlorine atom, a fluorine atom, or a fluorine atom-substituted alkyl group having a carbon number of not less than 1 and not more than 5, more preferably a chlorine atom, a fluorine atom, or a perfluoromethyl group, even more preferably a chlorine atom or a fluorine atom, and particularly preferably a chlorine atom. Note that a monomer (a) for which R¹ in formula (a) is a chlorine atom has excellent polymerizability, whereas a copolymer including a monomer unit (I) for which R¹ in formula (I) is a chlorine atom is also excellent in terms of ease of production.

Moreover, from a viewpoint of improving main chain scission properties of the polymer upon irradiation with exposure light and increasing efficiency of resist pattern formation, R³ and R⁴ in formula (I) and formula (a) are each preferably a hydrogen atom or an unsubstituted alkyl group, more preferably a hydrogen atom or an unsubstituted alkyl group having a carbon number of not less than 1 and not more than 5, and even more preferably a hydrogen atom.

The “fluorine atom-containing organic group” that can constitute R² in formula (I) and formula (a) may be a fluoroalkyl group, a fluoroalkoxyalkyl group, a fluoroalkoxyalkenyl group, or a group represented by L-Ar (in the formula, L is a fluorine atom-containing divalent linking group, and Ar is an optionally substituted aromatic ring group) without any specific limitations.

From a viewpoint of improving main chain scission properties of the copolymer upon irradiation with ionizing radiation or the like and increasing efficiency of resist pattern formation, the number of fluorine atoms in R² is preferably not less than 1 and not more than 11. The number of fluorine atoms in R² is more preferably 3 or more, and more preferably 4 or more, and is preferably 9 or less. Note that the carbon number of R² can be not less than 1 and not more than 12.

In particular, R² in formula (I) and formula (a) is more preferably a group represented by L-Ar from a viewpoint of improving sensitivity of the copolymer to ionizing radiation or the like.

The fluoroalkyl group constituting R² is preferably a monofluoromethyl group (number of fluorine atoms: 1; carbon number: 1), a monofluoroethyl group (number of fluorine atoms: 1; carbon number: 2), a 2,2-difluoroethyl group (number of fluorine atoms: 2; carbon number: 2), a 2,2,2-trifluoromethyl group (number of fluorine atoms: 3; carbon number: 1), a 2,2,2-trifluoroethyl group (number of fluorine atoms: 3; carbon number: 2), a 2,2,3,3,3-pentafluoropropyl group (number of fluorine atoms: 5; carbon number: 3), a 3,3,4,4,4-pentafluorobutyl group (number of fluorine atoms: 5; carbon number: 4), a 2-(perfluorobutyl)ethyl group (number of fluorine atoms: 9; carbon number: 6), a 1H,1H,3H-tetrafluoropropyl group (number of fluorine atoms: 4; carbon number: 3), a 1H,1H,5H-octafluoropentyl group (number of fluorine atoms: 8; carbon number: 5), a 1H-1-(trifluoromethyl)trifluoroethyl group (number of fluorine atoms: 6; carbon number: 3), a 1H,1H,3H-hexafluorobutyl group (number of fluorine atoms: 6; carbon number: 4), a 2,2,3,3,4,4,4-heptafluorobutyl group (number of fluorine atoms: 7; carbon number: 4), or a 1,2,2,2-tetrafluoro-1-(trifluoromethyl)ethyl group (number of fluorine atoms: 7; carbon number: 3), and more preferably a 2,2,3,3,3-pentafluoropropyl group, a 1H-1-(trifluoromethyl)trifluoroethyl group, a 1H,1H,3H-hexafluorobutyl group, a 2,2,3,3,4,4,4-heptafluorobutyl group, or a 1,2,2,2-tetrafluoro-1-(trifluoromethyl)ethyl group.

The fluoroalkoxyalkyl group constituting R² is preferably a pentafluoromethoxymethyl group (number of fluorine atoms: 5; carbon number: 2), a pentafluoroethoxymethyl group (number of fluorine atoms: 5; carbon number: 3), or a pentafluoroethoxyethyl group (number of fluorine atoms: 5; carbon number: 4), for example.

The fluoroalkoxyalkenyl group constituting R² is preferably a pentafluoroethoxyvinyl group (number of fluorine atoms: 5; carbon number: 4), for example.

The fluorine atom-containing divalent linking group that can constitute L in the group represented by L-Ar may be a fluorine atom-containing divalent chain alkylene group having a carbon number of not less than 1 and not more than 5, for example. Specifically, the fluorine atom-containing divalent linking group may be a trifluoromethylmethylene group, a pentafluoroethylmethylene group, or a bis(trifluoromethyl)methylene group, for example. In particular, a pentafluoroethylmethylene group or a bis(trifluoromethyl)methylene group is preferable, and a bis(trifluoromethyl)methylene group is more preferable.

The number of fluorine atoms in L is preferably 3 or more, more preferably 4 or more, and even more preferably 5 or more, and is preferably 11 or less, and more preferably 9 or less.

When the number of fluorine atoms in L is not less than any of the lower limits set forth above, sensitivity to exposure light can be even further improved.

On the other hand, when the number of fluorine atoms in Lis not more than any of the upper limits set forth above, production efficiency of the copolymer can be improved.

Ar in the group represented by L-Ar may be an optionally substituted aromatic hydrocarbon ring group or an optionally substituted aromatic heterocyclic group.

The aromatic hydrocarbon ring group may be a benzene ring group, a biphenyl ring group, a naphthalene ring group, an azulene ring group, an anthracene ring group, a phenanthrene ring group, a pyrene ring group, a chrysene ring group, a naphthacene ring group, a triphenylene ring group, an o-terphenyl ring group, an m-terphenyl ring group, a p-terphenyl ring group, an acenaphthene ring group, a coronene ring group, a fluorene ring group, a fluoranthene ring group, a pentacene ring group, a perylene ring group, a pentaphene ring group, a picene ring group, a pyranthrene ring group, or the like, for example, without any specific limitations.

The aromatic heterocyclic group may be a furan ring group, a thiophene ring group, a pyridine ring group, a pyridazine ring group, a pyrimidine ring group, a pyrazine ring group, a triazine ring group, an oxadiazole ring group, a triazole ring group, an imidazole ring group, a pyrazole ring group, a thiazole ring group, an indole ring group, a benzimidazole ring group, a benzothiazole ring group, a benzoxazole ring group, a quinoxaline ring group, a quinazoline ring group, a phthalazine ring group, a benzofuran ring group, a dibenzofuran ring group, a benzothiophene ring group, a dibenzothiophene ring group, a carbazole ring group, or the like, for example, without any specific limitations.

Examples of possible substituents of Ar include an alkyl group, a fluorine atom, and a fluoroalkyl group without any specific limitations. Examples of alkyl groups that are possible substituents of Ar include chain alkyl groups having a carbon number of not less than 1 and not more than 6 such as a methyl group, an ethyl group, a propyl group, an n-butyl group, and an isobutyl group. Examples of fluoroalkyl groups that are possible substituents of Ar include fluoroalkyl groups having a carbon number of not less than 1 and not more than 5 such as a trifluoromethyl group, a trifluoroethyl group, and a pentafluoropropyl group.

Of these examples, an optionally substituted aromatic hydrocarbon ring group is preferable as Ar from a viewpoint of improving sensitivity to exposure light, with an unsubstituted aromatic hydrocarbon ring group being more preferable, and a benzene ring group (phenyl group) being even more preferable.

From a viewpoint of improving sensitivity to exposure light, it is preferable that in formula (I) and formula (a), R² is a group represented by L-Ar, and more preferable that in formula (I) and formula (a), R¹ is a chlorine atom, R³ and R⁴ are each a hydrogen atom, and R² is a group represented by L-Ar.

The monomer (a) represented by formula (a) described above that can form the monomer unit (I) represented by formula (I) described above may be an α-chloroacrylic acid fluoroalkyl ester such as monofluoromethyl α-chloroacrylate, monofluoroethyl α-chloroacrylate, 2,2-difluoroethyl α-chloroacrylate, 2,2,2-trifluoroethyl α-chloroacrylate, 2,2,3,3,3-pentafluoropropyl α-chloroacrylate, 3,3,4,4,4-pentafluorobutyl chloroacrylate, 2-(perfluorobutyl)ethyl α-chloroacrylate, 1H,1H,3H-tetrafluoropropyl α-chloroacrylate, 1H,1H, 5H-octafluoropentyl chloroacrylate, 1H-1-(trifluoromethyl)trifluoroethyl α-chloroacrylate, 1H,1H,3H-hexafluorobutyl α-chloroacrylate, 2,2,3,3,4,4,4-heptafluorobutyl α-chloroacrylate, or 1,2,2,2-tetrafluoro-1-(trifluoromethyl)ethyl α-chloroacrylate; an α-fluoroacrylic acid fluoroalkyl ester such as 2,2,2-trifluoroethyl α-fluoroacrylate, 2,2,3,3,3-pentafluoropropyl α-fluoroacrylate, 3,3,4,4,4-pentafluorobutyl α-fluoroacrylate, 2-(perfluorobutyl)ethyl α-fluoroacrylate, 1H,1H,3H-tetrafluoropropyl α-fluoroacrylate, 1H,1H,5H-octafluoropentyl α-fluoroacrylate, 1H-1-(trifluoromethyl)trifluoroethyl α-fluoroacrylate, 1H,1H,3H-hexafluorobutyl α-fluoroacrylate, 2,2,3,3,4,4,4-heptafluorobutyl α-fluoroacrylate, or 1,2,2,2-tetrafluoro-1-(trifluoromethyl)ethyl α-fluoroacrylate; an α-chloroacrylic acid fluoroalkoxyalkyl ester such as pentafluoroethoxymethyl-chloroacrylate or pentafluoroethoxyethyl α-chloroacrylate; an α-fluoroacrylic acid fluoroalkoxyalkyl ester such as pentafluoroethoxymethyl α-fluoroacrylate or pentafluoroethoxyethyl α-fluoroacrylate; an α-chloroacrylic acid fluoroalkoxyalkenyl ester such as pentafluoroethoxyvinyl α-chloroacrylate; an α-fluoroacrylic acid fluoroalkoxyalkenyl ester such as pentafluoroethoxyvinyl α-fluoroacrylate; 1-phenyl-1-trifluoromethyl-2,2,2-trifluoroethyl α-chloroacrylate (ACAFPh); or the like, for example, without any specific limitations. One of these monomers can be used individually, or two or more of these monomers can be used in combination. Of these monomers, 1-phenyl-1-trifluoromethyl-2,2,2-trifluoroethyl α-chloroacrylate (ACAFPh) is preferable.

The proportion constituted by the monomer unit (I) in the copolymer when all monomer units in the copolymer are taken to be 100 mol % is preferably 20 mol % or more, more preferably 30 mol % or more, and even more preferably 40 mol % or more, and is preferably 80 mol % or less, more preferably 70 mol % or less, and even more preferably 65 mol % or less.

When the proportion constituted by the monomer unit (I) in the copolymer is within any of the ranges set forth above when all monomer units in the copolymer are taken to be 100 mol %, sensitivity to ionizing radiation or the like can be increased.

### <Monomer Unit (II)>

The monomer unit (II) that is included in the presently disclosed copolymer is a structural unit that is derived from a monomer (b) represented by the following formula (b).

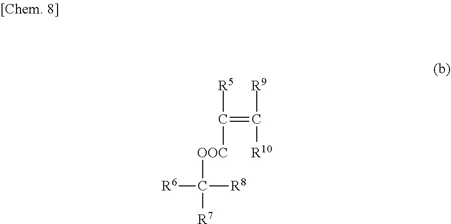

(In formula (b), R⁵ to R¹⁰ have the same meaning as in formula (II).)

The halogen atom or halogen atom-substituted alkyl group that can constitute R⁵ in formula (II) and formula (b) may be a halogen atom such as a chlorine atom, a fluorine atom, a bromine atom, or an iodine atom; or a group having a structure resulting from a portion of or all of the hydrogen atoms in an alkyl group being replaced by any of the above-described halogen atoms without any specific limitations.

Moreover, the alkyl group of the halogen atom-substituted alkyl group that can constitute R⁵ in formula (II) and formula (b) may be an unsubstituted alkyl group having a carbon number of not less than 1 and not more than 5 without any specific limitations. In particular, the alkyl group of the halogen atom-substituted alkyl group that can constitute R⁵ is preferably a methyl group or an ethyl group.

The “optionally substituted aliphatic group that does not include a fluorine atom” that can constitute R⁶, R⁷, and R⁸ in formula (II) and formula (b) is not specifically limited so long as it does not include a fluorine atom. From a viewpoint of even further widening the exposure margin while also forming a resist pattern having an even better shape, R⁶, R⁷, and R⁸ are each preferably an optionally substituted aliphatic group having a carbon number of not less than 1 and not more than 10 that does not include a fluorine atom, and more preferably an optionally substituted aliphatic group having a carbon number of not less than 1 and not more than 8 that does not include a fluorine atom. Note that the “carbon number” referred to above means the carbon number of the aliphatic group and is not inclusive of the carbon number of a substituent.

The aliphatic group may be a chain aliphatic group or a ring aliphatic group without any specific limitations.

The chain aliphatic group may be an alkyl group, an alkenyl group, or the like without any specific limitations.

The alkyl group may be an alkyl group having a carbon number of not less than 1 and not more than 20, for example, without any specific limitations. Specifically, the alkyl group may be a methyl group, an ethyl group, an n-propyl group, an isopropyl group, an n-butyl group, an isobutyl group, a tert-butyl group, a pentyl group, a hexyl group, a heptyl group, an octyl group, a nonyl group, a decyl group, or the like. In particular, a methyl group is preferable.

The alkenyl group may be an alkenyl group having a carbon number of not less than 1 and not more than 20, for example, without any specific limitations. Specifically, the alkenyl group may be an ethenyl group (vinyl group), a propenyl group, an isopropenyl group, a butenyl group, an isobutenyl group, a tert-butenyl group, a pentenyl group, a hexenyl group, a heptenyl group, an octenyl group, an isooctenyl group, a nonenyl group, or the like.

The ring aliphatic group may be monocyclic or polycyclic. The monocyclic ring aliphatic group may be a cycloalkyl group, a cycloalkenyl group, or the like.

The cycloalkyl group may be a cycloalkyl group having a carbon number of not less than 3 and not more than 20, for example, without any specific limitations. Specifically, the cycloalkyl group may be a cyclopropyl group, a cyclobutyl group, a cyclopentyl group, a cyclohexyl group, a cyclooctyl group, a cyclononyl group, a cyclodecyl group, or the like.

The cycloalkenyl group may be a cycloalkenyl group having a carbon number of not less than 3 and not more than 20, for example, without any specific limitations. Specifically, the cycloalkenyl group may be a 1-cyclopropenyl group, a 1-cyclobutenyl group, a 1-cyclopentenyl group, a 1-cyclohexenyl group, a 1-cycloheptenyl group, a 1-cyclooctenyl group, or the like.

Examples of possible substituents include a halogen atom such as a chlorine atom, a bromine atom, and an iodine atom, an amino group, a hydroxy group, a carboxyl group, a sulfonyl group, an alkyl group, a cycloalkyl group, an alkylamino group, a dialkylamino group, an alkoxy group, a thiol group, a sulfide group, and a thioester group without any specific limitations so long as they do not include a fluorine atom. The alkyl group, cycloalkyl group, alkylamino group, dialkylamino group, and alkoxy group mentioned above may be further substituted with any of the aforementioned halogen atoms, a hydroxy group, an amino group, a carboxyl group, or a sulfonyl group.

No specific limitations are placed on the number of substituents of each of R⁶, R⁷, and R⁸. In a case in which a plurality of substituents are present in R⁶, R⁷, or R⁸, these substituents may be the same as or different from one another.

The aforementioned alkyl group as a substituent may be any of those that were previously described as the alkyl group of R⁶, R⁷, and R⁸ without any specific limitations. In particular, an alkyl group having a carbon number of not less than 1 and not more than 4, and specifically a methyl group, an ethyl group, an n-propyl group, an isopropyl group, an isobutyl group, or a tert-butyl group is preferable.

The aforementioned cycloalkyl group as a substituent may be any of those that were previously described as the cycloalkyl group of R⁶, R⁷, and R⁸ without any specific limitations. In particular, a cycloalkyl group having a carbon number of not less than 3 and not more than 10 such as a cyclohexyl group, for example, is preferable.

The aforementioned alkoxy group as a substituent may be an alkoxy group having a carbon number of not less than 1 and not more than 12 such as a methoxy group, an ethoxy group, or a butoxy group, for example. In particular, a methoxy group is preferable.

The aforementioned alkylamino group as a substituent may be an alkylamino group having a carbon number of not less than 1 and not more than 12 such as a methylamino group, an ethylamino group, an n-propylamino group, an i-propylamino group, a cyclopropylamino group, an n-butylamino group, an i-butylamino group, an s-butylamino group, a t-butylamino group, or a cyclobutylamino group, for example.

The aforementioned dialkylamino group as a substituent may be a dialkylamino group having a carbon number of not less than 2 and not more than 12 such as a dimethylamino group, a diethylamino group, a dipropylamino group, or a dibutylamino group.

The ring structure formed by R⁶, R⁷, and R⁸ (more specifically, two or more selected from R⁶, R⁷, and R⁸) with a carbon atom that is bonded thereto may be monocyclic or polycyclic without any specific limitations so long as it does not include a fluorine atom.

The monocyclic ring structure may be a monocyclic aliphatic hydrocarbon ring such as a cyclopropane ring, a cyclobutane ring, a cyclopentane ring, a cyclohexane ring, a cycloheptane ring, a cyclooctane ring, a cyclononane ring, a cyclodecane ring, a cycloundecane ring, a cyclododecane ring, a cyclopentene ring, a cyclohexene ring, a cycloheptene ring, a cyclooctene ring, a cyclononane ring, a cyclodecene ring, or a cyclododecene ring; or a monocyclic aliphatic heteroring such as a lactone ring, a pyrrolidine ring, a tetrahydrothiophene ring, a piperidine, a tetrahydrothiopyran ring, a piperazine ring, a morpholine ring, or a dioxane ring without any specific limitations. Note that it is preferable that the monocyclic aliphatic heteroring is not a pyranose ring or a furanose ring. The term “heteroring” refers to a ring structure that includes at least one heteroatom other than carbon, and the heteroring may be a saturated ring or an unsaturated ring. Moreover, the heteroatom may be a nitrogen atom, an oxygen atom, or a sulfur atom without any specific limitations.

In particular, it is preferable that the monocyclic ring structure is an aliphatic hydrocarbon ring.

The polycyclic ring structure may be a polycyclic structure in which two or more monocycles are fused together, may be a polycyclic structure in which two or more rings are bonded via a single bond or a linking group, may be a polycyclo ring structure of two or more rings, or may be a spiro ring structure. Any of the previously described monocycles can be a monocycle that is a constituent of the polycyclic structure.

Specific examples of polycyclic structures include polycyclic aliphatic hydrocarbon rings such as a decalin ring, a hydrindane ring, an adamantane ring, a norbornane ring, a norbornene ring, an isobornane ring, a tricyclodecane ring, a tetracyclododecane ring, and a sterol ring; and polycyclic aliphatic heterorings such as a norbornane lactone ring, a 7-oxanorbornane ring, a 7-thionorbornane ring, and a 7-azanorbornane ring. In particular, an adamantane ring or a norbornane lactone ring is preferable.

These ring structures may include any of the previously described substituents. Moreover, in a case in which the ring structure includes two or more substituents, these substituents may be the same as or different from each other.

The unsubstituted alkyl group that can constitute R⁹ and R¹⁰ in formula (II) and formula (b) may be an unsubstituted alkyl group having a carbon number of not less than 1 and not more than 10 without any specific limitations. In particular, the unsubstituted alkyl group that can constitute R⁹ and R¹⁰ is preferably a methyl group or an ethyl group.

From a viewpoint of even further widening the exposure margin while also forming a resist pattern having an even better shape, it is preferable that in formula (II) and formula (b), R⁶, R⁷, and R⁸ are each a hydrogen atom or an optionally substituted aliphatic group having a carbon number of not less than 1 and not more than 10 that does not include a fluorine atom; more preferable that R⁵ is a chlorine atom, R⁶, R⁷, and R⁸ are each a hydrogen atom or form a polycyclic aliphatic hydrocarbon ring or a polycyclic aliphatic heteroring with a carbon atom that is bonded thereto, and R⁹ and R¹⁰ are each a hydrogen atom; and even more preferable that R⁵ is a chlorine atom, R⁶, R⁷, and R⁸ form an adamantyl ring or a norbornane lactone ring with a carbon atom that is bonded thereto, and R° and R¹⁰ are each a hydrogen atom.

Specific examples of the monomer (b) represented by formula (b) described above that can form the monomer unit (II) represented by formula (II) described above include, but are not specifically limited to, α-chloroacrylic acid alkyl esters such as methyl α-chloroacrylate, ethyl α-chloroacrylate, propyl α-chloroacrylate, butyl α-chloroacrylate, cyclohexyl α-chloroacrylate, and cycloheptyl α-chloroacrylate; α-fluoroacrylic acid alkyl esters such as methyl α-fluoroacrylate, ethyl α-fluoroacrylate, propyl α-fluoroacrylate, butyl α-fluoroacrylate, cyclohexyl α-fluoroacrylate, and cycloheptyl α-fluoroacrylate; 1-adamantyl α-chloroacrylate; 1-adamantyl α-fluoroacrylate; 1-adamantylmethyl α-chloroacrylate; 1-adamantylmethyl α-fluoroacrylate; 2-adamantyl α-chloroacrylate; 2-adamantyl α-fluoroacrylate; norbornane lactone α-chloroacrylate; norbornane lactone α-fluoroacrylate; gamma-butyrolactone α-chloroacrylate; and gamma-butyrolactone α-fluoroacrylate. One of these monomers can be used individually, or two or more of these monomers can be used in combination.

In particular, from a viewpoint of even further widening the exposure margin while also forming a resist pattern having an even better shape, methyl α-chloroacrylate, 2-adamantyl α-chloroacrylate, norbornane lactone α-chloroacrylate, or gamma-butyrolactone α-chloroacrylate is preferable as the monomer (b) represented by formula (b).

In other words, the copolymer preferably includes a methyl α-chloroacrylate unit represented by the following formula (b-1), a 2-adamantyl α-chloroacrylate unit represented by the following formula (b-2), a norbornane lactone α-chloroacrylate unit represented by the following formula (b-3), or a gamma-butyrolactone α-chloroacrylate unit represented by the following formula (b-4) as the monomer unit (II).

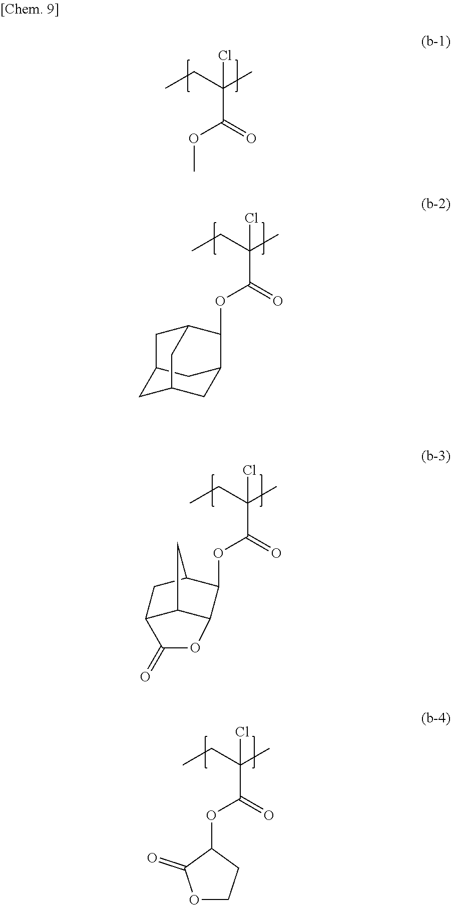

From a viewpoint of even further widening the exposure margin while also forming a resist pattern having an even better shape, the proportion constituted by the monomer unit (II) in the copolymer when all monomer units in the copolymer are taken to be 100 mol % is preferably 1.0 mol % or more, and more preferably 2.0 mol % or more, and is preferably less than 30 mol %, more preferably 25 mol % or less, and even more preferably 20 mol % or less.

Note that the total proportion constituted by the monomer unit (I) and the monomer unit (II) in the copolymer when all monomer units in the copolymer are taken to be 100 mol % is preferably 30 mol % or more, and more preferably 40 mol % or more, and is preferably 70 mol % or less, and more preferably 65 mol % or less.

### <Monomer Unit (III)>

The monomer unit (III) is a structural unit that is derived from a monomer (c) represented by the following formula (c).

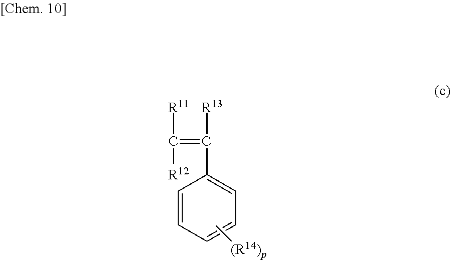

(In formula (c), R¹¹ to R¹⁴ and p have the same meaning as in formula (III).)

The unsubstituted alkyl group that can constitute R¹¹ and R¹² in formula (III) and formula (c) may be an alkyl group having a carbon number of not less than 1 and not more than 5 without any specific limitations. In particular, the alkyl group that can constitute R¹¹ and R¹² is preferably a methyl group or an ethyl group.

The alkyl group of the “optionally substituted alkyl group” that can constitute R¹³ in formula (III) and formula (c) may be an alkyl group having a carbon number of not less than 1 and not more than 5 without any specific limitations. In particular, the alkyl group that can constitute R¹³ is preferably a methyl group or an ethyl group. Examples of possible substituents include halogen atoms such as a chlorine atom, a fluorine atom, a bromine atom, and an iodine atom without any specific limitations. In a case in which the alkyl group that can constitute R¹³ is substituted with a halogen atom, a portion of or all of the hydrogen atoms in the alkyl group can be replaced by any of the above-described halogen atoms.

The halogen atom that can constitute R¹⁴ in formula (III) and formula (c) may be a halogen atom such as a chlorine atom, a fluorine atom, a bromine atom, or an iodine atom without any specific limitations. In particular, a fluorine atom is preferable.

The organic group that can constitute R¹⁴ in formula (III) and formula (c) may be an unsubstituted alkyl group, a halogen atom-substituted alkyl group, an alkoxy group, a halogen atom-substituted alkoxy group, or the like.

The unsubstituted alkyl group that can constitute R¹⁴ may be an unsubstituted alkyl group having a carbon number of not less than 1 and not more than 5 without any specific limitations. In particular, a methyl group or an ethyl group is preferable.

The halogen atom-substituted alkyl group that can constitute R¹⁴ may be a group having a structure resulting from a portion of or all of the hydrogen atoms in an alkyl group being replaced by any of the above-described halogen atoms without any specific limitations.

The alkoxy group that can constitute R¹⁴ may be an alkoxy group having a carbon number of not less than 1 and not more than 5 without any specific limitations. In particular, a methoxy group or an ethoxy group is preferable.

The halogen atom-substituted alkoxy group that can constitute R¹⁴ may be a group having a structure resulting from a portion of or all of the hydrogen atoms in an alkoxy group being replaced by any of the above-described halogen atoms without any specific limitations.

Note that in a case in which a plurality of R¹⁴ groups are present (i.e., a case in which p is an integer of not less than 2 and not more than 5), these R¹⁴ groups may be the same as or different from one another.

Examples of the monomer (c) represented by formula (c) include, but are not specifically limited to, α-methylstyrene (AMS) and derivatives thereof such as the following monomers (c-1) to (c-14).

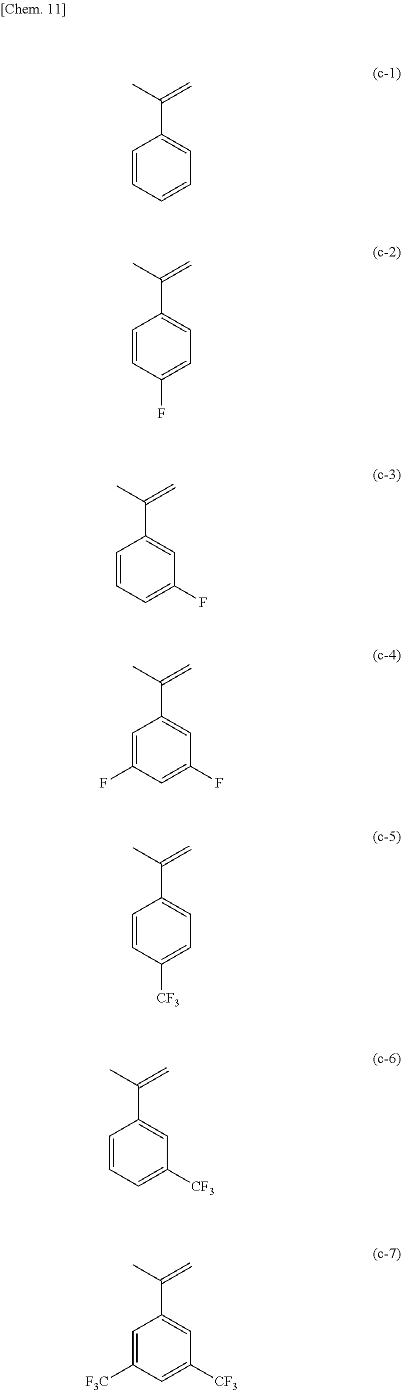

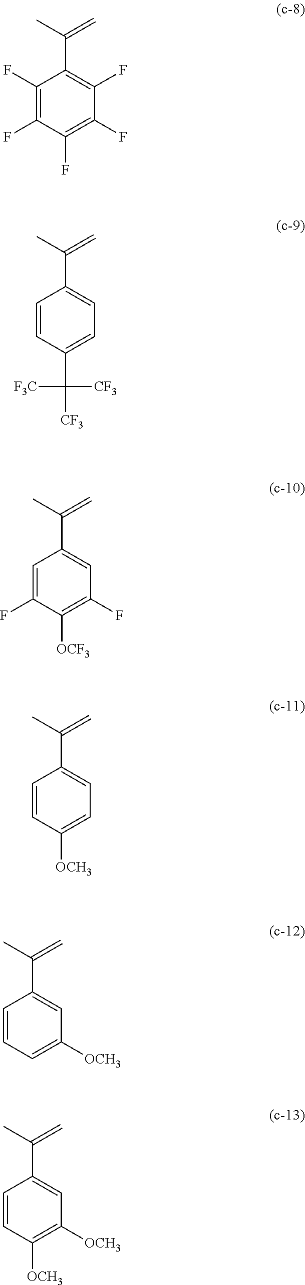 [SMILES: C=C(C)c1c(F)c(F)c(F)c(F)c1F ; C=C(C)c1ccc(C(C(F)(F)F)(C(F)(F)F)C(F)(F)F)cc1 ; C=C(C)c1cc(F)c(OC(F)(F)F)c(F)c1 ; C=C(C)c1ccc(OC)cc1 ; C=C(C)c1cccc(OC)c1 ; C=C(C)c1ccc(OC)c(OC)c1]

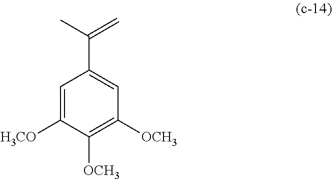

Note that from a viewpoint of improving ease of production of the copolymer, it is preferable that the monomer unit (III) does not include a fluorine atom, and more preferable that the monomer unit (III) is a structural unit derived from α-methylstyrene. In other words, it is preferable that in formula (III) and formula (c), R¹¹ and R¹² are each a hydrogen atom, R¹³ is a methyl group, and p=0.

The proportion constituted by the monomer unit (III) in the copolymer is not specifically limited, but when all monomer units in the copolymer are taken to be 100 mol %, this proportion is preferably 20 mol % or more, more preferably 30 mol % or more, and even more preferably 40 mol % or more, and is preferably 80 mol % or less, preferably 75 mol % or less, and more preferably 70 mol % or less.

### <Properties of Copolymer>

### [Weight-Average Molecular Weight (Mw)]

The weight-average molecular weight (Mw) of the copolymer is preferably 20,000 or more, more preferably 50,000 or more, and even more preferably 300,000 or more, and is preferably 500,000 or less, more preferably 400,000 or less, and even more preferably 350,000 or less.

When the weight-average molecular weight (Mw) of the copolymer is not less than any of the lower limits set forth above, solubility of a resist film in a developer can be inhibited from increasing excessively at a low irradiation dose, and a resist pattern having an even better shape can be formed.

On the other hand, when the weight-average molecular weight (Mw) of the copolymer is not more than any of the upper limits set forth above, a positive resist composition can easily be produced.

Note that the “weight-average molecular weight” referred to in the present specification can be measured by a method described in the EXAMPLES section.

### [Number-Average Molecular Weight (Mn)]

The number-average molecular weight (Mn) of the copolymer is preferably 7,000 or more, more preferably 10,000 or more, and even more preferably 20,000 or more, and is preferably 200,000 or less, more preferably 150,000 or less, even more preferably 140,000 or less, and further preferably 100,000 or less.

When the number-average molecular weight of the copolymer is not less than any of the lower limits set forth above, solubility of a resist film in a developer can be further inhibited from increasing excessively at a low irradiation dose, and a resist pattern having an even better shape can be formed.

On the other hand, when the number-average molecular weight of the copolymer is not more than any of the upper limits set forth above, a positive resist composition can more easily be produced.

Note that the “number-average molecular weight” referred to in the present specification can be measured by a method described in the EXAMPLES section.

### [Molecular Weight Distribution (Mw/Mn)]

The molecular weight distribution (Mw/Mn) of the copolymer is preferably 1.10 or more, more preferably 1.20 or more, and even more preferably 1.50 or more, and is preferably 3.00 or less, more preferably 2.70 or less, and even more preferably 2.50 or less.

When the molecular weight distribution (Mw/Mn) of the copolymer is not less than any of the lower limits set forth above, ease of production of the copolymer can be increased.

On the other hand, when the molecular weight distribution (Mw/Mn) of the copolymer is not more than any of the upper limits set forth above, an obtained resist pattern can be provided with an even better shape.

Note that the “molecular weight distribution” referred to in the present specification can be determined by calculating a ratio of the weight-average molecular weight relative to the number-average molecular weight (weight-average molecular weight/number-average molecular weight).

### <Production Method of Copolymer>

No specific limitations are placed on the method by which the copolymer is produced. For example, the copolymer including the monomer unit (I), the monomer unit (II), and the monomer unit (III) can be produced by polymerizing a monomer composition containing the monomer (a), the monomer (b), the monomer (c), and an optional monomer that is copolymerizable with these monomers, subsequently collecting the resultant copolymer, and optionally purifying the copolymer.

Note that the chemical composition, molecular weight distribution, number-average molecular weight, and weight-average molecular weight of the copolymer can be adjusted by altering the polymerization conditions and the purification conditions. Specifically, the number-average molecular weight and the weight-average molecular weight can be increased by lowering the polymerization temperature, for example. Moreover, the number-average molecular weight and the weight-average molecular weight can be increased by shortening the polymerization time. Furthermore, the molecular weight distribution can be reduced by performing purification.

### [Polymerization of Monomer Composition]

The monomer composition that is used to produce the copolymer can, for example, be a mixture of monomer components including the monomer (a), the monomer (b), the monomer (c), and an optional monomer that is copolymerizable with these monomers, an optionally used solvent, an optionally used polymerization initiator, and optionally added additives. Polymerization of the monomer composition may be carried out by a known method. In particular, it is preferable that cyclopentanone, water, or the like is used as the solvent. Moreover, it is preferable that azobisisobutyronitrile, dimethyl 2,2′-azobis(2-methylpropionate), or the like, for example, is used as the polymerization initiator.

A polymerized product obtained through polymerization of the monomer composition can be collected by adding a good solvent such as tetrahydrofuran to a solution containing the polymerized product and subsequently dripping the solution to which the good solvent has been added into a poor solvent such as methanol, ethanol, 1-propanol, 1-butanol, 1-pentanol, or hexane to cause coagulation of the polymerized product, but is not specifically limited to being collected in this manner.

### [Purification of Polymerized Product]

The method of purification in a case in which the obtained polymerized product is purified may be, but is not specifically limited to, a known purification method such as reprecipitation or column chromatography. Of these purification methods, purification by reprecipitation is preferable.

Also note that purification of the polymerized product may be repeated multiple times.

Purification of the polymerized product by reprecipitation is preferably performed by, for example, dissolving the obtained polymerized product in a good solvent such as tetrahydrofuran, subsequently dripping the resultant solution into a mixed solvent of a good solvent such as tetrahydrofuran and a poor solvent such as methanol, ethanol, 1-propanol, 1-butanol, 1-pentanol, or hexane, and causing a portion of the polymerized product to precipitate. When purification of the polymerized product is performed by dripping a solution of the polymerized product into a mixed solvent of a good solvent and a poor solvent in this manner, the molecular weight distribution, number-average molecular weight, and weight-average molecular weight of the resultant copolymer can easily be adjusted by altering the types and/or mixing ratio of the good solvent and the poor solvent. Specifically, the molecular weight of copolymer that precipitates in the mixed solvent can be increased by increasing the proportion of the good solvent in the mixed solvent, for example.

In a case in which the polymerized product is purified by reprecipitation, polymerized product that has precipitated in the mixed solvent of the good solvent and the poor solvent may be used as the copolymer or polymerized product that has not precipitated in the mixed solvent (i.e., polymerized product that is dissolved in the mixed solvent) may be used as the copolymer so long as the polymerized product that is used satisfies the desired properties. Polymerized product that has not precipitated in the mixed solvent can be collected from the mixed solvent by a known technique such as concentrating to dryness.

### (Positive Resist Composition)

The presently disclosed positive resist composition contains the presently disclosed copolymer and a solvent. The presently disclosed positive resist composition can increase the exposure margin of an obtained resist while also forming a resist pattern having a good shape as a result of containing the presently disclosed copolymer set forth above.

### <Copolymer>

The presently disclosed copolymer set forth above can be used as the copolymer.

The proportional content of the copolymer in the positive resist composition when the total of all components of the positive resist composition is taken to be 100 mass % is preferably 0.5 mass % or more, more preferably 1 mass % or more, and even more preferably 1.5 mass % or more, and is preferably 15 mass % or less, more preferably 10 mass % or less, and even more preferably 5 mass % or less.

### <Solvent>

The solvent is not specifically limited so long as it is a solvent in which the presently disclosed copolymer can dissolve. For example, known solvents such as those described in JP5938536B1 can be used. Of such solvents, anisole, propylene glycol monomethyl ether acetate (PGMEA), cyclopentanone, cyclohexanone, or isoamyl acetate is preferable as the solvent from a viewpoint of obtaining a positive resist composition of suitable viscosity and improving coatability of the positive resist composition, with isoamyl acetate being more preferable.

### <Other Components>

The presently disclosed positive resist composition may optionally further contain known additives that can be compounded in resist compositions in addition to the components described above. Additives can be added in appropriate amounts according to the application without any specific limitations on the amount thereof.

### <Production of Positive Resist Composition>

The positive resist composition can be produced by mixing the presently disclosed copolymer, the solvent, and known additives that can optionally be used. The method of mixing is not specifically limited and may be mixing by a commonly known method. Moreover, production may be performed by filtering the mixture after mixing of components.

### [Filtration]

No specific limitations are placed on the method by which the mixture is filtered. For example, the mixture can be filtered using a filter. The filter is not specifically limited and may, for example, be a filtration membrane based on a fluorocarbon, cellulose, nylon, polyester, hydrocarbon, or the like. In particular, from a viewpoint of effectively preventing impurities such as metals from becoming mixed into the positive resist composition from metal piping or the like that may be used in production of the presently disclosed copolymer, the constituent material of the filter is preferably polyethylene, polypropylene, a polyfluorocarbon such as polytetrafluoroethylene or Teflon® (Teflon is a registered trademark in Japan, other countries, or both), tetrafluoroethylene-perfluoroalkyl vinyl ether copolymer (PFA), nylon, a composite membrane of polyethylene and nylon, or the like. For example, a filter disclosed in U.S. Pat. No. 6,103,122A may be used as the filter. Moreover, the filter may be a commercially available product such as Zeta Plus® 40Q (Zeta Plus is a registered trademark in Japan, other countries, or both) produced by CUNO Incorporated. Furthermore, the filter may be a filter that contains a strongly cationic or weakly cationic ion exchange resin. The average particle diameter of the ion exchange resin is not specifically limited but is preferably not less than 2 μm and not more than 10 μm. Examples of cation exchange resins that may be used include a sulfonated phenol-formaldehyde condensate, a sulfonated phenol-benzaldehyde condensate, a sulfonated styrene-divinylbenzene copolymer, a sulfonated methacrylic acid-divinylbenzene copolymer, and other types of sulfo or carboxy group-containing polymers. In the cation exchange resin, H⁺ counter ions, NH₄⁺ counter ions, or alkali metal counter ions such as K⁺ or Na⁺ counter ions are provided. The cation exchange resin preferably includes hydrogen counter ions. One example of such a cation exchange resin is Microlite® PrCH (Microlite is a registered trademark in Japan, other countries, or both) produced by Purolite, which is a sulfonated styrene-divinylbenzene copolymer including H⁺ counter ions. Another example of such a cation exchange resin is commercially available as AMBERLYST® (AMBERLYST is a registered trademark in Japan, other countries, or both) produced by Rohm and Haas Company.

The pore diameter of the filter is preferably not less than 0.001 μm and not more than 1 μm. When the pore diameter of the filter is within the range set forth above, it is possible to sufficiently prevent impurities such as metals from being mixed into the positive resist composition.

### (Method of Forming Resist Pattern)

The presently disclosed method of forming a resist pattern includes at least a step of forming a resist film using the presently disclosed positive resist composition set forth above (resist film formation step), a step of exposing the resist film (exposure step), and a step of developing the resist film that has been exposed (exposure step).

Moreover, the presently disclosed method of forming a resist pattern may, for example, include a step of forming an underlayer film on a substrate on which the resist film is to be formed (underlayer film formation step) in advance of the resist film formation step. Furthermore, the presently disclosed method of forming a resist pattern may further include a step of heating the resist film (post exposure bake (PEB) step) between the exposure step and the development step and/or a step of removing a developer (developer removal step) after the development step. Also, a step of etching the underlayer film and/or the substrate (etching step) may be further included after a resist pattern has been formed by the method of forming a resist pattern.

In the presently disclosed method of forming a resist pattern, a resist pattern having a good shape can be formed with a wide exposure margin as a result of the presently disclosed positive resist composition being used as a positive resist composition.

### <Underlayer Film Formation Step>

In the underlayer film formation step that can optionally be performed before the resist film formation step, an underlayer film is formed on the substrate. Through provision of the underlayer film on the substrate, the surface of the substrate is hydrophobized. This can increase affinity of the substrate and a resist film and can increase close adherence between the substrate and the resist film. The underlayer film may be an inorganic underlayer film or an organic underlayer film.

An inorganic underlayer film can be formed by applying an inorganic material onto the substrate and then performing firing or the like of the inorganic material. The inorganic material may be a silicon-based material or the like, for example.

An organic underlayer film can be formed by applying an organic material onto the substrate to form a coating film and then drying the coating film. The organic material is not limited to being a material that is sensitive to light or an electron beam and may be a resist material or resin material that is typically used in the field of semiconductors or the field of liquid crystals, for example. In particular, the organic material is preferably a material that can form an organic underlayer film that can be etched, and particularly dry etched. By using such an organic material, it is possible to etch the organic underlayer film using a pattern formed through processing of a resist film, and to thereby transfer the pattern to the underlayer film and form an underlayer film pattern. In particular, the organic material is preferably a material that can form an organic underlayer film that can be etched by oxygen plasma etching or the like. For example, AL412 produced by Brewer Science, Inc. or the like may be used as an organic material that is used to form an organic underlayer film.

Application of the organic material described above can be performed by spin coating or a conventional and commonly known method using a spinner or the like. The method by which the coating film is dried may be any method that can cause volatilization of solvent contained in the organic material. For example, a method in which baking is performed or the like may be adopted. Although no specific limitations are placed on the baking conditions, the baking temperature is preferably not lower than 80° C. and not higher than 300° C., and more preferably not lower than 200° C. and not higher than 300° C. Moreover, the baking time is preferably 30 seconds or more, and more preferably 60 seconds or more, and is preferably 500 seconds or less, more preferably 400 seconds or less, even more preferably 300 seconds or less, and particularly preferably 180 seconds or less. Furthermore, the thickness of the underlayer film after drying of the coating film is not specifically limited but is preferably not less than 10 nm and not more than 100 nm.

### [Substrate]

The substrate on which the underlayer film or resist film can be formed in the method of forming a resist pattern is not specifically limited and may be a substrate including an electrically insulating layer and copper foil on the electrically insulating layer that is used in production of a printed board or the like; or a mask blank including a light shielding layer formed on a substrate.

The material of the substrate may, for example, be an inorganic material such as a metal (silicon, copper, chromium, iron, aluminum, etc.), glass, titanium oxide, silicon dioxide (SiO₂), silica, or mica; a nitride such as SiN; an oxynitride such as SiON; or an organic material such as acrylic, polystyrene, cellulose, cellulose acetate, or phenolic resin. Of these materials, a metal is preferable as the material of the substrate. By using a silicon substrate, a silicon dioxide substrate, or a copper substrate, and preferably a silicon substrate or a silicon dioxide substrate as the substrate, for example, it is possible to form a structure having a cylinder structure.

No specific limitations are placed on the size and shape of the substrate. Note that the surface of the substrate may be smooth or may have a curved or irregular shape, and that a substrate having a flake shape or the like may be used.

The surface of the substrate may be subjected to surface treatment as necessary. For example, in the case of a substrate having hydroxy groups in a surface layer thereof, the substrate can be surface treated using a silane coupling agent that can react with hydroxy groups. This makes it possible to convert the surface layer of the substrate from hydrophilic to hydrophobic and to increase close adherence between the substrate and an underlayer film or between the substrate and a resist layer. The silane coupling agent is not specifically limited but is preferably hexamethyldisilazane.

### <Resist Film Formation Step>

In the resist film formation step, the presently disclosed positive resist composition is applied onto a workpiece such as a substrate that is to be processed using a resist pattern (onto an underlayer film in a case in which an underlayer film has been formed) to form a coating layer (application step), and the solvent is then removed from the obtained coating layer to form a resist film (drying step).

### [Application Step]

The workpiece onto which the presently disclosed positive resist composition is applied in the application step is not specifically limited and may be a semiconductor substrate that is used in production of a semiconductor device or the like; a substrate including an electrically insulating layer and copper foil provided on the electrically insulating layer that is used in production of a printed board or the like; or a mask blank including a light shielding layer formed on a substrate. A known method can be adopted without any specific limitations as the application method of the presently disclosed positive resist composition.

### [Drying Step]

No specific limitations are placed on the method by which the solvent is removed from the coating layer. Although any drying method that is typically used in resist film formation can be adopted, it is preferable that the positive resist composition is heated (prebaked) to form the resist film.

The temperature at which the coating layer is dried (drying temperature) is preferably 100° C. or higher, and more preferably 110° C. or higher from a viewpoint of close adherence between the workpiece and the resist film that is formed through the drying step, and is preferably 250° C. or lower, and more preferably 200° C. or lower from a viewpoint of reducing the effect of heat on the workpiece and the resist film. Moreover, the time for which the coating layer is dried (drying time) is preferably more than 10 seconds, more preferably 30 seconds or more, and even more preferably 1 minute or more from a viewpoint of implementing the drying step in a lower temperature range and sufficiently improving close adherence between the formed resist film and the workpiece, and is preferably 60 minutes or less, and more preferably 30 minutes or less from a viewpoint of reducing change of molecular weight of the polymer in the resist film between before and after the drying step.

### <Exposure Step>

In the exposure step, the resist film formed in the resist film formation step is irradiated with ionizing radiation or the like to write a desired pattern. Note that exposure with ionizing radiation or the like can be performed using a known writing tool such as an electron beam lithography tool or an EUV exposure tool.

Ionizing radiation referred to here is radiation having sufficient energy for causing ionization of atoms or molecules. In contrast, non-ionizing radiation is radiation that does not have sufficient energy for causing ionization of atoms or molecules.

The ionizing radiation may be an electron beam, extreme ultraviolet radiation, gamma rays, X-rays, alpha rays, a heavy particle beam, a proton beam, beta rays, an ion beam, or the like. In particular, an electron beam or extreme ultraviolet radiation is preferable as the ionizing radiation, with an electron beam being more preferable. The wavelength of the extreme ultraviolet radiation is not specifically limited, but can be set as not less than 1 nm and not more than 30 nm, and preferably set as 13.5 nm, for example.

The non-ionizing radiation is preferably non-ionizing radiation having a wavelength of 300 nm or less, but is not specifically limited thereto. The non-ionizing radiation having a wavelength of 300 nm or less may be far ultraviolet radiation other than extreme ultraviolet radiation (wavelength=not less than 40 nm and not more than 200 nm), near ultraviolet radiation (wavelength=more than 200 nm and not more than 300 nm), or the like. In particular, a KrF excimer laser beam (wavelength=248 nm) or an ArF excimer laser beam (wavelength=193 nm) is preferable.

### <Post Exposure Bake Step>

In the post exposure bake step that can optionally be performed, the resist film that has been exposed in the exposure step is heated. By performing the post exposure bake step, it is possible to reduce the surface roughness of a resist pattern.

The heating temperature is preferably 70° C. or higher, more preferably 80° C. or higher, and even more preferably 90° C. or higher, and is preferably 200° C. or lower, more preferably 170° C. or lower, and even more preferably 150° C. or lower. When the heating temperature is within any of the ranges set forth above, clarity of a resist pattern can be increased while also favorably reducing surface roughness of the resist pattern.

The time for which the resist film is heated (heating time) in the post exposure bake step is preferably 10 seconds or more, more preferably 20 seconds or more, and even more preferably 30 seconds or more. When the heating time is 10 seconds or more, clarity of a resist pattern can be further increased while also sufficiently reducing surface roughness of the resist pattern. On the other hand, the heating time is preferably 10 minutes or less, more preferably 5 minutes or less, and even more preferably 3 minutes or less, for example, from a viewpoint of production efficiency.

The method by which the resist film is heated in the post exposure bake step is not specifically limited and may, for example, be a method in which the resist film is heated by a hot plate, a method in which the resist film is heated in an oven, or a method in which hot air is blown against the resist film.

### <Development Step>

In the development step, the resist film that has been exposed (resist film that has been exposed and heated in a case in which the post exposure bake step is performed) is developed to form a developed film on the workpiece.

Development of the resist film can be performed by bringing the resist film into contact with a developer, for example. The method by which the resist film and the developer are brought into contact may be, but is not specifically limited to, a method using a known technique such as immersion of the resist film in the developer or application of the developer onto the resist film.

### [Developer]

The developer can be selected as appropriate depending on properties of the presently disclosed copolymer, for example. Specifically, in selection of the developer, it is preferable to select a developer that does not dissolve the resist film prior to the exposure step being performed but that can dissolve an exposed part of the resist film that has undergone the exposure step. One developer may be used individually, or two or more developers may be used as a mixture in a freely selected ratio.

Examples of developers that can be used include fluorinated solvents such as hydrofluorocarbons (1,1,1,2,3,4,4,5,5,5-decafluoropentane (CF₃CFHCFHCF₂CF₃), 1,1,1,2,2,3,3,4,4,5,5,6,6-tridecafluorohexane, 1,1,1,3,3-pentafluorobutane, 1,1,1,2,2,3,4,5,5,5-decafluoropentane, 1,1,1,2,2,3,3,4,4-nonafluorohexane, etc.), hydrochlorofluorocarbons (2,2-dichloro-1,1,1-trifluoroethane, 1,1-dichloro-1-fluoroethane, 1,1-dichloro-2,2,3,3,3-pentafluoropropane (CF₃CF₂CHCl₂), 1,3-dichloro-1,1,2,2,3-pentafluoropropane (CClF₂CF₂CHClF), etc.), hydrofluoroethers (methyl nonafluorobutyl ether (CF₃CF₂CF₂CF₂OCH₃), methyl nonafluoroisobutyl ether, ethyl nonafluorobutyl ether (CF₃CF₂CF₂CF₂OC₂H₅), ethyl nonafluoroisobutyl ether, perfluorohexyl methyl ether (CF₃CF₂CF(OCH₃)C₃F₇), etc.), and perfluorocarbons (CF₄, C₂F₆, C₃F₈, C₄F₈, C₄F₁₀, C₅F₁₂, C₆F₁₂, C₆F₁₄, C₇F₁₄, C₇F₁₆, C₈F₁₈, C₉F₂₀, etc.); alcohol solvents such as methanol, ethanol, 1-propanol, 2-propanol (isopropyl alcohol), 1-butanol, 2-butanol, 1-pentanol, 2-pentanol, and 3-pentanol; alkyl group-containing acetic acid ester solvents such as amyl acetate and hexyl acetate; mixtures of a fluorinated solvent and an alcohol solvent; mixtures of a fluorinated solvent and an alkyl group-containing acetic acid ester solvent; mixtures of an alcohol solvent and an alkyl group-containing acetic acid ester solvent; and mixtures of a fluorinated solvent, an alcohol solvent, and an alkyl group-containing acetic acid ester solvent. Of these examples, it is preferable to use an alcohol solvent as the developer from a viewpoint of imparting an even better shape to a resist pattern, with isopropyl alcohol being more preferable.

### <Developer Removal Step>

In the developer removal step that is optionally included in the method of forming a resist pattern, the developer is removed from the developed resist film to form a resist pattern on the workpiece.

Removal of the developer can be performed by air blowing using a gas such as nitrogen or by rinsing treatment using a rinsing liquid.

In the rinsing treatment, the method by which the developed resist film and the rinsing liquid are brought into contact may be, but is not specifically limited to, a method using a known technique such as immersion of the resist film in the rinsing liquid or application of the rinsing liquid onto the resist film. Specific examples of rinsing liquids that may be used include the same liquids as the developers given as examples in the “Development step” section, and also water and hydrocarbon solvents such as octane and heptane, for example. The rinsing liquid may contain a surfactant. In selection of the rinsing liquid, it is preferable to select a rinsing liquid that, compared to the developer used in the development step, has a lower tendency to dissolve the resist film prior to the exposure step being performed and that readily mixes with the developer.

### <Etching Step>

In the etching step that can optionally be performed, etching of the underlayer film and/or the substrate is performed using the above-described resist pattern as a mask so as to form a pattern in the underlayer film and/or substrate.

The number of times that etching is performed is not specifically limited and may be once or a plurality of times. Moreover, the etching may be dry etching or wet etching, but is preferably dry etching. The dry etching can be performed using a commonly known dry etching apparatus. An etching gas that is used in the dry etching can be selected as appropriate depending on the element composition of the underlayer film or substrate that is to be etched, for example. Examples of etching gases that may be used include fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCl, NO, and BCl₃; and inert gases such as He, N₂, and Ar. One of these gases may be used individually, or two or more of these gases may be used as a mixture. Note that dry etching of an inorganic underlayer film is normally performed using an oxygen-based gas. Moreover, dry etching of a substrate is normally performed using a fluorine-based gas and may suitably be performed using a mixture of a fluorine-based gas and an inert gas.

Underlayer film remaining on the substrate may be removed before etching of the substrate or after etching of the substrate as necessary. In a case in which the underlayer film is removed before etching of the substrate is performed, this underlayer film may be an underlayer film in which a pattern is formed or may be an underlayer film in which a pattern is not formed.

The method by which the underlayer film is removed may, for example, be dry etching such as described above. In the case of an inorganic underlayer film, the underlayer film may be removed by bringing a liquid such as a basic liquid or an acidic liquid, and preferably a basic liquid into contact with the underlayer film. The basic liquid is not specifically limited and may be alkaline hydrogen peroxide aqueous solution or the like, for example. The method by which the underlayer film is removed through wet stripping using alkaline hydrogen peroxide aqueous solution is not specifically limited so long as it is a method in which the underlayer film and alkaline hydrogen peroxide aqueous solution can be brought into contact under heated conditions for a specific time and may, for example, be a method in which the underlayer film is immersed in heated alkaline hydrogen peroxide aqueous solution, a method in which alkaline hydrogen peroxide aqueous solution is sprayed against the underlayer film in a heated environment, or a method in which heated alkaline hydrogen peroxide aqueous solution is applied onto the underlayer film. After any of these methods is performed, the substrate may be washed with water and then dried to thereby obtain a substrate from which the underlayer film has been removed.

The following describes one example of a method of forming a resist pattern using the presently disclosed positive resist composition and a method of etching an underlayer film and a substrate using a resist pattern that is formed. However, since the substrate, conditions of each step, and so forth in the following example can be the same as the substrate, conditions of each step, and so forth described above, description thereof is omitted below. Note that the method of forming a resist pattern is not limited to the method presented in the following example.

One example of the method of forming a resist pattern is a method of forming a resist pattern using an electron beam or EUV that includes the previously described underlayer film formation step, resist film formation step, exposure step, development step, and developer removal step. Moreover, one example of the etching method is a method in which a resist pattern formed by the method of forming a resist pattern is used as a mask and that includes an etching step.

Specifically, in the underlayer film formation step, an inorganic material is applied onto a substrate and is fired to form an inorganic underlayer film.

Next, in the resist film formation step, the presently disclosed positive resist composition is applied onto the inorganic underlayer film that has been formed in the underlayer film formation step and is dried to form a resist film.

Next, in the exposure step, the resist film that has been formed in the resist film formation step is irradiated with EUV so as to write a desired pattern.

Moreover, in the development step, the resist film that has been exposed in the exposure step and a developer are brought into contact to develop the resist film and form a resist pattern on the underlayer film.

Furthermore, in the developer removal step, the resist film that has been developed in the development step and a rinsing liquid are brought into contact to rinse the developed resist film.

Next, in the etching step, the resist pattern is used as a mask to etch the underlayer film and thereby form a pattern in the underlayer film.

Next, the underlayer film in which the pattern has been formed is used as a mask to etch the substrate and thereby form a pattern in the substrate.

### EXAMPLES

The following provides a more specific description of the present disclosure based on examples. However, the present disclosure is not limited to these examples. Moreover, in the case of a copolymer that is produced through copolymerization of a plurality of types of monomers, the proportion constituted in the copolymer by a monomer unit that is formed through polymerization of a given monomer is normally, unless otherwise specified, the same as the ratio (charging ratio) of the given monomer among all monomers used in polymerization of the copolymer.

Furthermore, in the examples and comparative examples, the following methods were used to measure or calculate the proportions of monomer units in a copolymer and the number-average molecular weight, weight-average molecular weight, and molecular weight distribution of a copolymer. Also, in the examples and comparative examples, the following methods were used to evaluate the exposure margin of a resist and the shape of a resist pattern.

### <Proportions of Monomer Units in Copolymer>

For each copolymer obtained in the examples and comparative examples, the proportion constituted by each monomer unit in the copolymer was calculated by ¹³C-NMR.

Specifically, each copolymer obtained in the examples and comparative examples was dissolved in chloroform-d, 99.8% (produced by FUJIFILM Wako Pure Chemical Corporation) such as to have a concentration of 10 mass %, and then this solution was used to calculate the proportion constituted by each monomer unit in the copolymer through use of a nuclear magnetic resonance spectrometer (produced by JEOL Ltd.; 500 MHz).

### <Number-Average Molecular Weight, Weight-Average Molecular Weight, and Molecular Weight Distribution>

For each copolymer obtained in the examples and comparative examples, the number-average molecular weight (Mn) and weight-average molecular weight (Mw) were measured by gel permeation chromatography, and then the molecular weight distribution (Mw/Mn) was calculated.

Specifically, the number-average molecular weight (Mn) and the weight-average molecular weight (Mw) of the copolymer were determined as standard polystyrene-equivalent values with tetrahydrofuran as an eluent solvent using a gel permeation chromatograph (HLC-8420 produced by Tosoh Corporation). The molecular weight distribution (Mw/Mn) was then calculated.

### <Exposure Margin>

Each positive resist composition obtained in the examples and comparative examples was used to form a resist pattern and to evaluate the exposure margin.

Specifically, a spin coater (MS-A150 produced by Mikasa Co., Ltd.) was first used to apply the positive resist composition onto a silicon wafer of 4 inches in diameter such as to have a thickness of 50 nm. Next, the applied positive resist composition was heated by a hot plate having a temperature of 170° C. for 1 minute to form a resist film on the silicon wafer (resist film formation step). The thickness of the resist film was 50 nm. Next, an electron beam lithography tool (ELS-S50 produced by Elionix Inc.) was used to expose the resist film with an irradiation dose that was varied in a range of 100 μC/cm² to 400 μC/cm² in increments of 10 μC/cm² so as to write a pattern (exposure step). The resist film present after the exposure step was subjected to 1 minute of development treatment at a temperature of 23° C. using isopropyl alcohol (IPA) as a developer (development step). Thereafter, the developer was removed by nitrogen blowing to thereby form a resist pattern (developer removal step).

The presence or absence of pattern separation and pattern collapse of the formed resist pattern was inspected. Lines (non-exposed regions) and spaces (exposed regions) of the resist pattern were each set as 30 nm.

The exposure margin was evaluated in accordance with the following standard. The results are shown in Table 1.
A: Difference between exposure dose at which pattern separation starts and exposure dose at which pattern collapse occurs is 50 μC/cm² or more
B: Difference between exposure dose at which pattern separation starts and exposure dose at which pattern collapse occurs is not less than 10 μC/cm² and less than 50 μC/cm²
C: Difference between exposure dose at which pattern separation starts and exposure dose at which pattern collapse occurs is less than 10 μC/cm²

### <Shape of Resist Pattern>

Each positive resist composition obtained in the examples and comparative examples was used to form a resist pattern and to evaluate the resist pattern shape.

Specifically, a scanning electron microscope was used to inspect the shape of a pattern that had been exposed with an exposure dose corresponding to a central value of an exposure dose range from pattern separation to pattern collapse in evaluation of the exposure margin described above. The shape of the resist pattern was evaluated in accordance with the following standard. The results are shown in Table 1.
A: Side wall shape of resist pattern is smooth
B: Side wall shape of resist pattern is rough

### Example 1

### <Production of Copolymer A1>

A glass vessel was charged with a monomer composition A1 containing 5.98 g of 1-phenyl-1-trifluoromethyl-2,2,2-trifluoroethyl α-chloroacrylate (ACAFPh) as a monomer (a), 0.48 g of 2-adamantyl α-chloroacrylate (ACA2Ad) as a monomer (b), 3.54 g of α-methylstyrene (AMS) as a monomer (c), 0.00013 g of V-601 (dimethyl 2,2′-azobis(2-methylpropionate)) as a polymerization initiator, and 6.66 g of cyclopentanone as a solvent. The glass vessel was tightly sealed and purged with nitrogen, and was then stirred under a nitrogen atmosphere inside a 78° C. constant-temperature tank for 6 hours.

Thereafter, the glass vessel was returned to room temperature, the inside of the glass vessel was opened to the atmosphere, and then 16.69 g of THF (tetrahydrofuran) was added to the resultant solution. Next, the solution to which THF had been added was added dropwise to 400 g of methanol as a solvent to cause precipitation of a polymerized product. Thereafter, the solution containing the polymerized product that had precipitated was filtered using a Kiriyama funnel to obtain a white coagulated material (copolymer A1). Upon calculation of the proportions of monomer units in the obtained copolymer A1 by 13C-NMR, the copolymer A1 was determined to be a polymer comprising 47.2 mol % of 1-phenyl-1-trifluoromethyl-2,2,2-trifluoroethyl α-chloroacrylate units as monomer units (I), 3.4 mol % of 2-adamantyl α-chloroacrylate units as monomer units (II), and 49.4 mol % of α-methylstyrene units as monomer units (III).

Thereafter, the number-average molecular weight, weight-average molecular weight, and molecular weight distribution of the obtained copolymer A1 were measured. The results are shown in Table 1.

### <Production of Positive Resist Composition>

The copolymer A1 produced as described above was dissolved in isoamyl acetate as a solvent to produce a positive resist composition of 2 mass % in concentration.

The obtained positive resist composition was used to form a resist pattern and to evaluate the exposure margin and resist pattern shape. The results are shown in Table 1.

### Example 2

Various operations, measurements, and evaluations were performed in the same way as in Example 1 with the exception that in production of a copolymer, a monomer composition A2 containing 5.98 g of 1-phenyl-1-trifluoromethyl-2,2,2-trifluoroethyl α-chloroacrylate (ACAFPh) as a monomer (a), 0.48 g of norbornane lactone α-chloroacrylate (ACANBL) as a monomer (b), 3.54 g of α-methylstyrene (AMS) as a monomer (c), 0.00017 g of V-601 (dimethyl 2,2′-azobis(2-methylpropionate)) as a polymerization initiator, and 6.62 g of cyclopentanone as a solvent was produced instead of the monomer composition A1. The results are shown in Table 1.

The obtained copolymer A2 was a copolymer comprising 45.1 mol % of 1-phenyl-1-trifluoromethyl-2,2,2-trifluoroethyl α-chloroacrylate units as monomer units (I), 4.2 mol % of norbornane lactone α-chloroacrylate units as monomer units (II), and 50.7 mol % of α-methylstyrene units as monomer units (III).

### Example 3

Various operations, measurements, and evaluations were performed in the same way as in Example 1 with the exception that in production of a copolymer, a monomer composition A3 containing 6.13 g of 1-phenyl-1-trifluoromethyl-2,2,2-trifluoroethyl α-chloroacrylate (ACAFPh) as a monomer (a), 0.25 g of methyl α-chloroacrylate (ACAM) as a monomer (b), 3.63 g of α-methylstyrene (AMS) as a monomer (c), 0.0024 g of V-601 (dimethyl 2,2′-azobis(2-methylpropionate)) as a polymerization initiator, and 6.42 g of cyclopentanone as a solvent was produced instead of the monomer composition A1. The results are shown in Table 1.

The obtained copolymer A3 was a copolymer comprising 47.4 mol % of 1-phenyl-1-trifluoromethyl-2,2,2-trifluoroethyl α-chloroacrylate units as monomer units (I), 2.8 mol % of methyl α-chloroacrylate units as monomer units (II), and 49.8 mol % of α-methylstyrene units as monomer units (III).

### Example 4

Various operations, measurements, and evaluations were performed in the same way as in Example 1 with the exception that a copolymer A4 produced as described below was used instead of the copolymer A1. The results are shown in Table 1.

### [Production of Polymer]

A glass vessel was charged with a monomer composition A4 containing 10.23 g of 1-phenyl-1-trifluoromethyl-2,2,2-trifluoroethyl α-chloroacrylate (ACAFPh) as a monomer (a), 0.82 g of 2-adamantyl α-chloroacrylate (ACA2Ad) as a monomer (b), 6.04 g of α-methylstyrene (AMS) as a monomer (c), and 0.174 g of V-601 (dimethyl 2,2′-azobis(2-methylpropionate)) as a polymerization initiator. In addition, 55.48 g of sodium laurate aqueous solution having a solid content of 7.5% was added, the glass vessel was tightly sealed and purged with nitrogen, and then the glass vessel was stirred under a nitrogen atmosphere inside a 75° C. constant-temperature tank for 3 hours.

Thereafter, the glass vessel was returned to room temperature, the inside of the glass vessel was opened to the atmosphere, and the resultant solution was added dropwise to 569.21 g of methanol to cause precipitation of a polymer. The precipitated polymer was subsequently collected by filtration. [Purification of polymer]

The polymer that had been collected by filtration was dissolved in 41.02 g of THF, and then a mixed solution of 187.14 g of THF and 325.57 g of methanol was added dropwise to the resultant solution to cause precipitation of a white coagulated material (polymer). Thereafter, the polymer was collected by decantation, was dissolved in 27.34 g of THF, and the resultant solution was added dropwise to 273.44 g of methanol to cause precipitation of a polymer. Thereafter, the solution containing the polymer that had precipitated was filtered using a Kiriyama funnel to obtain a coagulated material (copolymer A4).

Upon calculation of the proportions of monomer units in the obtained copolymer A4 by 13C-NMR, the copolymer A4 was determined to be a copolymer comprising 47.1 mol % of 1-phenyl-1-trifluoromethyl-2,2,2-trifluoroethyl α-chloroacrylate units as monomer units (I), 5.5 mol % of 2-adamantyl α-chloroacrylate units as monomer units (II), and 47.4 mol % of α-methylstyrene units as monomer units (III).

### Example 5

Various operations, measurements, and evaluations were performed in the same way as in Example 4 with the exception that in production of a copolymer, a monomer composition A5 containing 10.21 g of 1-phenyl-1-trifluoromethyl-2,2,2-trifluoroethyl α-chloroacrylate (ACAFPh) as a monomer (a), 0.83 g of norbornane lactone α-chloroacrylate (ACANBL) as a monomer (b), 6.04 g of α-methylstyrene (AMS) as a monomer (c), and 0.168 g of V-601 (dimethyl 2,2′-azobis(2-methylpropionate)) as a polymerization initiator was produced instead of the monomer composition A4. The results are shown in Table 1.

The obtained copolymer A5 was a polymer comprising 51.7 mol % of 1-phenyl-1-trifluoromethyl-2,2,2-trifluoroethyl α-chloroacrylate units as monomer units (I), 2.5 mol % of norbornane lactone α-chloroacrylate units as monomer units (II), and 45.8 mol % of α-methylstyrene units as monomer units (III).

### Example 6

Various operations, measurements, and evaluations were performed in the same way as in Example 4 with the exception that in production of a copolymer, a monomer composition A6 containing 10.20 g of 1-phenyl-1-trifluoromethyl-2,2,2-trifluoroethyl α-chloroacrylate (ACAFPh) as a monomer (a), 0.41 g of methyl α-chloroacrylate (ACAM) as a monomer (b), 6.04 g of α-methylstyrene (AMS) as a monomer (c), and 0.190 g of V-601 (dimethyl 2,2′-azobis(2-methylpropionate)) as a polymerization initiator was produced instead of the monomer composition A4. The results are shown in Table 1.

The obtained copolymer A6 was a polymer comprising 50.8 mol % of 1-phenyl-1-trifluoromethyl-2,2,2-trifluoroethyl α-chloroacrylate units as monomer units (I), 2.9 mol % of methyl α-chloroacrylate units as monomer units (II), and 46.3 mol % of α-methylstyrene units as monomer units (III).

### Example 7

Various operations, measurements, and evaluations were performed in the same way as in Example 1 with the exception that in production of a copolymer, a monomer composition A7 containing 3.25 g of 1-phenyl-1-trifluoromethyl-2,2,2-trifluoroethyl α-chloroacrylate (ACAFPh) as a monomer (a), 0.59 g of 2-adamantyl α-chloroacrylate (ACA2Ad) as a monomer (b), 2.16 g of α-methylstyrene (AMS) as a monomer (c), 0.00011 g of V-601 (dimethyl 2,2′-azobis(2-methylpropionate)) as a polymerization initiator, and 3.97 g of cyclopentanone as a solvent was produced instead of the monomer composition A1. The results are shown in Table 1.

The obtained copolymer A7 was a polymer comprising 46.9 mol % of 1-phenyl-1-trifluoromethyl-2,2,2-trifluoroethyl α-chloroacrylate units as monomer units (I), 4.4 mol % of 2-adamantyl α-chloroacrylate units as monomer units (II), and 48.7 mol % of α-methylstyrene units as monomer units (III).

### Example 8

Various operations, measurements, and evaluations were performed in the same way as in Example 1 with the exception that in production of a copolymer, a monomer composition A8 containing 3.25 g of 1-phenyl-1-trifluoromethyl-2,2,2-trifluoroethyl α-chloroacrylate (ACAFPh) as a monomer (a), 0.59 g of norbornane lactone α-chloroacrylate (ACANBL) as a monomer (b), 2.16 g of α-methylstyrene (AMS) as a monomer (c), 0.00011 g of V-601 (dimethyl 2,2′-azobis(2-methylpropionate)) as a polymerization initiator, and 3.97 g of cyclopentanone as a solvent was produced instead of the monomer composition A1. The results are shown in Table 1.

The obtained copolymer A8 was a polymer comprising 47.3 mol % of 1-phenyl-1-trifluoromethyl-2,2,2-trifluoroethyl α-chloroacrylate units as monomer units (I), 8.2 mol % of norbornane lactone α-chloroacrylate units as monomer units (II), and 44.5 mol % of α-methylstyrene units as monomer units (III).

### Example 9

Various operations, measurements, and evaluations were performed in the same way as in Example 1 with the exception that in production of a copolymer, a monomer composition A9 containing 3.42 g of 1-phenyl-1-trifluoromethyl-2,2,2-trifluoroethyl α-chloroacrylate (ACAFPh) as a monomer (a), 0.31 g of methyl α-chloroacrylate (ACAM) as a monomer (b), 2.28 g of α-methylstyrene (AMS) as a monomer (c), 0.00011 g of V-601 (dimethyl 2,2′-azobis(2-methylpropionate)) as a polymerization initiator, and 3.97 g of cyclopentanone as a solvent was produced instead of the monomer composition A1. The results are shown in Table 1.

The obtained copolymer A9 was a polymer comprising 44.2 mol % of 1-phenyl-1-trifluoromethyl-2,2,2-trifluoroethyl α-chloroacrylate units as monomer units (I), 9.2 mol % of methyl α-chloroacrylate units as monomer units (II), and 46.6 mol % of α-methylstyrene units as monomer units (III).

### Example 10

Various operations, measurements, and evaluations were performed in the same way as in Example 1 with the exception that in production of a copolymer, a monomer composition A10 containing 5.98 g of 1-phenyl-1-trifluoromethyl-2,2,2-trifluoroethyl α-chloroacrylate (ACAFPh) as a monomer (a), 0.38 g of gamma-butyrolactone α-chloroacrylate (ACAGBL) as a monomer (b), 3.54 g of α-methylstyrene (AMS) as a monomer (c), 0.00017 g of V-601 (dimethyl 2,2′-azobis(2-methylpropionate)) as a polymerization initiator, and 6.72 g of cyclopentanone as a solvent was produced instead of the monomer composition A1. The results are shown in Table 1.

The obtained copolymer A10 was a copolymer comprising 46.1 mol % of 1-phenyl-1-trifluoromethyl-2,2,2-trifluoroethyl α-chloroacrylate units as monomer units (I), 4.8 mol % of gamma-butyrolactone α-chloroacrylate units as monomer units (II), and 49.1 mol % of α-methylstyrene units as monomer units (III).

### Example 11

Various operations, measurements, and evaluations were performed in the same way as in Example 1 with the exception that in production of a copolymer, a monomer composition A11 containing 3.25 g of 1-phenyl-1-trifluoromethyl-2,2,2-trifluoroethyl α-chloroacrylate (ACAFPh) as a monomer (a), 0.46 g of gamma-butyrolactone α-chloroacrylate (ACAGBL) as a monomer (b), 2.16 g of α-methylstyrene (AMS) as a monomer (c), 0.00011 g of V-601 (dimethyl 2,2′-azobis(2-methylpropionate)) as a polymerization initiator, and 4.12 g of cyclopentanone as a solvent was produced instead of the monomer composition A1. The results are shown in Table 1.

The obtained copolymer A11 was a polymer comprising 47.2 mol % of 1-phenyl-1-trifluoromethyl-2,2,2-trifluoroethyl α-chloroacrylate units as monomer units (I), 8.5 mol % of gamma-butyrolactone α-chloroacrylate units as monomer units (II), and 44.3 mol % of α-methylstyrene units as monomer units (III).

### Example 12

Various operations, measurements, and evaluations were performed in the same way as in Example 4 with the exception that in production of a copolymer, a monomer composition A12 containing 10.22 g of 1-phenyl-1-trifluoromethyl-2,2,2-trifluoroethyl α-chloroacrylate (ACAFPh) as a monomer (a), 0.65 g of gamma-butyrolactone α-chloroacrylate (ACAGBL) as a monomer (b), 6.03 g of α-methylstyrene (AMS) as a monomer (c), and 0.169 g of V-601 (dimethyl 2,2′-azobis(2-methylpropionate)) as a polymerization initiator was produced instead of the monomer composition A4. The results are shown in Table 1.

The obtained copolymer A12 was a polymer comprising 50.8 mol % of 1-phenyl-1-trifluoromethyl-2,2,2-trifluoroethyl α-chloroacrylate units as monomer units (I), 2.4 mol % of gamma-butyrolactone α-chloroacrylate units as monomer units (II), and 46.8 mol % of α-methylstyrene units as monomer units (III).

### Comparative Example 1

Various operations, measurements, and evaluations were performed in the same way as in Example 1 with the exception that in production of a copolymer, a monomer composition A13 containing 11.07 g of 1-phenyl-1-trifluoromethyl-2,2,2-trifluoroethyl α-chloroacrylate (ACAFPh) as a monomer (a), 3.93 g of α-methylstyrene (AMS) as a monomer (c), 0.012 g of V-601 (dimethyl 2,2′-azobis(2-methylpropionate)) as a polymerization initiator, and 8.73 g of cyclopentanone as a solvent was produced instead of the monomer composition A1. The results are shown in Table 1.

The obtained copolymer A13 was a polymer comprising 51.6 mol % of 1-phenyl-1-trifluoromethyl-2,2,2-trifluoroethyl α-chloroacrylate units as monomer units (I) and 48.4 mol % of α-methylstyrene units as monomer units (III).

### Comparative Example 2

Various operations, measurements, and evaluations were performed in the same way as in Example 1 with the exception that in production of a copolymer, a monomer composition A14 containing 2.70 g of 2-adamantyl α-chloroacrylate (ACA2Ad) as a monomer (b), 5.30 g of α-methylstyrene (AMS) as a monomer (c), 0.0019 g of V-601 (dimethyl 2,2′-azobis(2-methylpropionate)) as a polymerization initiator, and 4.99 g of cyclopentanone as a solvent was produced instead of the monomer composition A1. The results are shown in Table 1. A resist formed using the obtained copolymer A14 could not be developed, and a resist pattern could not be obtained. Consequently, the exposure margin and the pattern shape could not be evaluated.

The obtained copolymer A14 was a polymer comprising 52.0 mol % of 2-adamantyl α-chloroacrylate units as monomer units (II) and 48.0 mol % of α-methylstyrene units as monomer units (III).

### Comparative Example 3

Various operations, measurements, and evaluations were performed in the same way as in Example 1 with the exception that in production of a copolymer, a monomer composition A15 containing 3.36 g of norbornane lactone α-chloroacrylate (ACANBL) as a monomer (b), 1.64 g of α-methylstyrene (AMS) as a monomer (c), 0.0051 g of V-601 (dimethyl 2,2′-azobis(2-methylpropionate)) as a polymerization initiator, and 2.83 g of cyclopentanone as a solvent was produced instead of the monomer composition A1. The results are shown in Table 1. A resist formed using the obtained copolymer A15 could not be developed, and a resist pattern could not be obtained. Consequently, the exposure margin and the pattern shape could not be evaluated. Moreover, the copolymer A15 did not dissolve in tetrahydrofuran, and measurement of molecular weight by gel permeation chromatography could not be performed.

The obtained copolymer A15 was a polymer comprising 57.4 mol % of norbornane lactone α-chloroacrylate units as monomer units (II) and 42.6 mol % of α-methylstyrene units as monomer units (III).

### Comparative Example 4

Various operations, measurements, and evaluations were performed in the same way as in Example 1 with the exception that in production of a copolymer, a monomer composition A16 containing 7.57 g of methyl α-chloroacrylate (ACAM) as a monomer (b), 7.43 g of α-methylstyrene (AMS) as a monomer (c), 0.023 g of V-601 (dimethyl 2,2′-azobis(2-methylpropionate)) as a polymerization initiator, and 7.60 g of cyclopentanone as a solvent was produced instead of the monomer composition A1. The results are shown in Table 1. A resist formed using the obtained copolymer A16 could not be developed, and a resist pattern could not be obtained. Consequently, the exposure margin and the pattern shape could not be evaluated.

The obtained copolymer A16 was a polymer comprising 58.3 mol % of methyl α-chloroacrylate units as monomer units (II) and 41.7 mol % of α-methylstyrene units as monomer units (III).

### Comparative Example 5

Various operations, measurements, and evaluations were performed in the same way as in Example 1 with the exception that in production of a copolymer, a monomer composition A17 containing 3.48 g of 1-phenyl-1-trifluoromethyl-2,2,2-trifluoroethyl α-chloroacrylate (ACAFPh) as a monomer (a), 2.52 g of 2-adamantyl α-chloroacrylate (ACA2Ad) as a monomer (b), 0.00048 g of V-601 (dimethyl 2,2′-azobis(2-methylpropionate)) as a polymerization initiator, and 3.88 g of cyclopentanone as a solvent was produced instead of the monomer composition A1. The results are shown in Table 1.

The obtained copolymer A17 was a polymer comprising 51.0 mol % of 1-phenyl-1-trifluoromethyl-2,2,2-trifluoroethyl α-chloroacrylate units as monomer units (I) and 49.0 mol % of 2-adamantyl α-chloroacrylate units as monomer units (II).

### Comparative Example 6

Various operations, measurements, and evaluations were performed in the same way as in Example 1 with the exception that in production of a copolymer, a monomer composition A18 containing 3.47 g of 1-phenyl-1-trifluoromethyl-2,2,2-trifluoroethyl α-chloroacrylate (ACAFPh) as a monomer (a), 2.53 g of norbornane lactone α-chloroacrylate (ACANBL) as a monomer (b), 0.00048 g of V-601 (dimethyl 2,2′-azobis(2-methylpropionate)) as a polymerization initiator, and 3.88 g of cyclopentanone as a solvent was produced instead of the monomer composition A1. The results are shown in Table 1. A resist formed using the obtained copolymer A18 could not be developed, and a resist pattern could not be obtained. Consequently, the exposure margin and the pattern shape could not be evaluated.

The obtained copolymer A18 was a polymer comprising 43.0 mol % of 1-phenyl-1-trifluoromethyl-2,2,2-trifluoroethyl α-chloroacrylate units as monomer units (I) and 57.0 mol % of norbornane lactone α-chloroacrylate units as monomer units (II).

### Comparative Example 7

Various operations, measurements, and evaluations were performed in the same way as in Example 1 with the exception that in production of a copolymer, a monomer composition A19 containing 4.43 g of 1-phenyl-1-trifluoromethyl-2,2,2-trifluoroethyl α-chloroacrylate (ACAFPh) as a monomer (a), 1.60 g of methyl α-chloroacrylate (ACAM) as a monomer (b), 0.00061 g of V-601 (dimethyl 2,2′-azobis(2-methylpropionate)) as a polymerization initiator, and 3.80 g of cyclopentanone as a solvent was produced instead of the monomer composition A1. The results are shown in Table 1.

The obtained copolymer A19 was a polymer comprising 32.4 mol % of 1-phenyl-1-trifluoromethyl-2,2,2-trifluoroethyl α-chloroacrylate units as monomer units (I) and 67.6 mol % of methyl α-chloroacrylate units as monomer units (II).

### Comparative Example 8

Various operations, measurements, and evaluations were performed in the same way as in Example 1 with the exception that in production of a copolymer, a monomer composition A20 containing 2.66 g of gamma-butyrolactone α-chloroacrylate (ACAGBL) as a monomer (b), 1.65 g of α-methylstyrene (AMS) as a monomer (c), 0.0051 g of V-601 (dimethyl 2,2′-azobis(2-methylpropionate)) as a polymerization initiator, and 3.63 g of cyclopentanone as a solvent was produced instead of the monomer composition A1. The results are shown in Table 1. A resist formed using the obtained copolymer A20 could not be developed, and a resist pattern could not be obtained. Consequently, the exposure margin and the pattern shape could not be evaluated. Moreover, the copolymer A20 did not dissolve in tetrahydrofuran, and measurement of molecular weight by gel permeation chromatography could not be performed.

The obtained copolymer A20 was a polymer comprising 55.8 mol % of gamma-butyrolactone α-chloroacrylate units as monomer units (II) and 44.2 mol % of α-methylstyrene units as monomer units (III).

### Comparative Example 9

Various operations, measurements, and evaluations were performed in the same way as in Example 1 with the exception that in production of a copolymer, a monomer composition A21 containing 3.48 g of 1-phenyl-1-trifluoromethyl-2,2,2-trifluoroethyl α-chloroacrylate (ACAFPh) as a monomer (a), 2.01 g of gamma-butyrolactone α-chloroacrylate (ACAGBL) as a monomer (b), 0.00049 g of V-601 (dimethyl 2,2′-azobis(2-methylpropionate)) as a polymerization initiator, and 4.50 g of cyclopentanone as a solvent was produced instead of the monomer composition A1. The results are shown in Table 1. A resist formed using the obtained copolymer A21 could not be developed, and a resist pattern could not be obtained. Consequently, the exposure margin and the pattern shape could not be evaluated.

The obtained copolymer A21 was a polymer comprising 43.8 mol % of 1-phenyl-1-trifluoromethyl-2,2,2-trifluoroethyl α-chloroacrylate units as monomer units (I) and 56.2 mol % of gamma-butyrolactone α-chloroacrylate units as monomer units (II).

TABLE 1

| | | | | | Proportions of | | | |
|---|---|---|---|---|---|---|---|---|
| | Copolymer | | | | monomer units (mol %) | | | |
| | | Monomer | Monomer | Monomer | Monomer | Monomer | Monomer | |
| | Type | unit (I) | unit (II) | unit (III) | unit (I) | unit (II) | unit (III) | Mw |
| Example 1 | Copolymer A1 | ACAFPh | ACA2Ad | AMS | 47.2 | 3.4 | 49.4 | 57000 |
| Example 2 | Copolymer A2 | ACAFPh | ACANBL | AMS | 45.1 | 4.2 | 50.7 | 54000 |
| Example 3 | Copolymer A3 | ACAFPh | ACAM | AMS | 47.4 | 2.8 | 49.8 | 58000 |
| Example 4 | Copolymer A4 | ACAFPh | ACA2Ad | AMS | 47.1 | 5.5 | 47.4 | 332000 |
| Example 5 | Copolymer A5 | ACAFPh | ACANBL | AMS | 51.7 | 2.5 | 45.8 | 340000 |
| Example 6 | Copolymer A6 | ACAFPh | ACAM | AMS | 50.8 | 2.9 | 46.3 | 320000 |
| Example 7 | Copolymer A7 | ACAFPh | ACA2Ad | AMS | 46.9 | 4.4 | 48.7 | 60000 |
| Example 8 | Copolymer A8 | ACAFPh | ACANBL | AMS | 47.3 | 8.2 | 44.5 | 55000 |
| Example 9 | Copolymer A9 | ACAFPh | ACAM | AMS | 44.2 | 9.2 | 46.6 | 59000 |
| Example 10 | Copolymer A10 | ACAFPh | ACAGBL | AMS | 46.1 | 4.8 | 49.1 | 48000 |
| Example 11 | Copolymer A11 | ACAFPh | ACAGBL | AMS | 47.2 | 8.5 | 44.3 | 51000 |
| Example 12 | Copolymer A12 | ACAFPh | ACAGBL | AMS | 50.8 | 2.4 | 46.8 | 320000 |
| Comparative | Copolymer A13 | ACAFPh | — | AMS | 51.6 | — | 48.4 | 60000 |
| Example 1 | | | | | | | | |
| Comparative | Copolymer A14 | — | ACA2Ad | AMS | — | 52.0 | 48.0 | 52000 |
| Example 2 | | | | | | | | |
| Comparative | Copolymer A15 | — | ACANBL | AMS | — | 57.4 | 42.6 | Cannot be |
| Example 3 | | | | | | | | measured |
| Comparative | Copolymer A16 | — | ACAM | AMS | — | 58.3 | 41.7 | 58000 |
| Example 4 | | | | | | | | |
| Comparative | Copolymer A17 | ACAFPh | ACA2Ad | — | 51.0 | 49.0 | — | 452000 |
| Example 5 | | | | | | | | |
| Comparative | Copolymer A18 | ACAFPh | ACANBL | — | 43.0 | 57.0 | — | 44000 |
| Example 6 | | | | | | | | |
| Comparative | Copolymer A19 | ACAFPh | ACAM | — | 32.4 | 67.6 | — | 449000 |
| Example 7 | | | | | | | | |
| Comparative | Copolymer A20 | — | ACAGBL | AMS | — | 55.8 | 44.2 | Cannot be |
| Example 8 | | | | | | | | measured |
| Comparative | Copolymer A21 | ACAFPh | ACAGBL | — | 43.8 | 56.2 | — | 42000 |
| Example 9 | | | | | | | | |

| | | | Pattern | | | | Resist |
|---|---|---|---|---|---|---|---|
| | | Prebake | exposure | Development | | Exposure | pattern |
| | Mw/Mn | Conditions | Type | Developer | Condition | margin | shape |
| Example 1 | 1.68 | 170° C. | EB lithography | IPA | 1 min | B | A |
| | | 1 min | | | | | |
| Example 2 | 1.62 | 170° C. | EB lithography | IPA | 1 min | B | A |
| | | 1 min | | | | | |
| Example 3 | 1.67 | 170° C. | EB lithography | IPA | 1 min | B | A |
| | | 1 min | | | | | |
| Example 4 | 2.25 | 170° C. | EB lithography | IPA | 1 min | A | A |
| | | 1 min | | | | | |
| Example 5 | 1.84 | 170° C. | EB lithography | IPA | 1 min | A | A |
| | | 1 min | | | | | |
| Example 6 | 1.70 | 170° C. | EB lithography | IPA | 1 min | A | A |
| | | 1 min | | | | | |
| Example 7 | 1.73 | 170° C. | EB lithography | IPA | 1 min | B | A |
| | | 1 min | | | | | |
| Example 8 | 1.69 | 170° C. | EB lithography | IPA | 1 min | A | A |
| | | 1 min | | | | | |
| Example 9 | 1.72 | 170° C. | EB lithography | IPA | 1 min | A | A |
| | | 1 min | | | | | |
| Example 10 | 1.59 | 170° C. | EB lithography | IPA | 1 min | B | A |
| | | 1 min | | | | | |
| Example 11 | 1.71 | 170° C. | EB lithography | IPA | 1 min | B | A |
| | | 1 min | | | | | |
| Example 12 | 1.75 | 170° C. | EB lithography | IPA | 1 min | A | A |
| | | 1 min | | | | | |
| Comparative | 1.80 | 170° C. | EB lithography | IPA | 1 min | C | B |
| Example 1 | | 1 min | | | | | |
| Comparative | 1.63 | 170° C. | EB lithography | IPA | 1 min | Cannot be | Cannot be |
| Example 2 | | 1 min | | | | measured | measured |
| Comparative | Cannot be | 170° C. | EB lithography | IPA | 1 min | Cannot be | Cannot be |
| Example 3 | measured | 1 min | | | | measured | measured |
| Comparative | 1.65 | 170° C. | EB lithography | IPA | 1 min | Cannot be | Cannot be |
| Example 4 | | 1 min | | | | measured | measured |
| Comparative | 2.19 | 170° C. | EB lithography | IPA | 1 min | C | B |
| Example 5 | | 1 min | | | | | |
| Comparative | 2.03 | 170° C. | EB lithography | IPA | 1 min | Cannot be | Cannot be |
| Example 6 | | 1 min | | | | measured | measured |
| Comparative | 2.05 | 170° C. | EB lithography | IPA | 1 min | C | C |
| Example 7 | | 1 min | | | | | |
| Comparative | Cannot be | 170° C. | EB lithography | IPA | 1 min | Cannot be | Cannot be |
| Example 8 | measured | 1 min | | | | measured | measured |
| Comparative | 2.11 | 170° C. | EB lithography | IPA | 1 min | Cannot be | Cannot be |
| Example 9 | | 1 min | | | | measured | measured |

In Table 1:
“EB” indicates electron beam;
“ACAFPh” indicates 1-phenyl-1-trifluoromethyl-2,2,2-trifluoroethyl α-chloroacrylate unit;
“ACAM” indicates methyl α-chloroacrylate unit;
“ACANBL” indicates norbornane lactone α-chloroacrylate unit;
“ACAGBL” indicates gamma-butyrolactone α-chloroacrylate unit;
“ACA2Ad” indicates 2-adamantyl α-chloroacrylate unit;
“AMS” indicates α-methylstyrene unit; and
“IPA” indicates isopropyl alcohol.

It can be seen from the results shown in Table 1 that there is a wide exposure margin and that a resist pattern having a good shape can be formed in Examples 1 to 12 in which the used copolymer includes the specific monomer units (I) to (III).

### INDUSTRIAL APPLICABILITY

According to the present disclosure, it is possible to provide a copolymer and a positive resist composition that have a wide exposure margin and that can form a resist pattern having a good shape.

Moreover, according to the present disclosure, it is possible to provide a method of forming a resist pattern that has a wide exposure margin and that can form a resist pattern having a good shape.

1. A copolymer comprising:
a monomer unit (I) represented by formula (I), shown below: 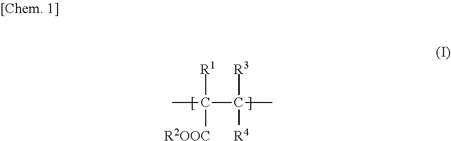
where, in formula (I), R¹ is a halogen atom or a halogen atom-substituted alkyl group, R² is a fluorine atom-containing organic group, and R³ and R⁴ are each a hydrogen atom, a halogen atom, an unsubstituted alkyl group, or a halogen atom-substituted alkyl group and may be the same as or different from each other;
a monomer unit (II) represented by formula (II), shown below: 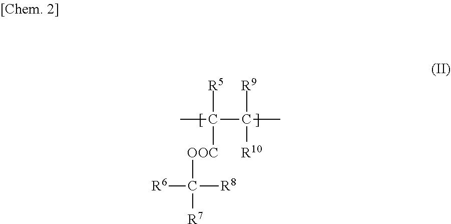
where, in formula (II), R⁵ is a halogen atom or a halogen atom-substituted alkyl group, R⁶, R⁷, and R⁸ are each a hydrogen atom or an optionally substituted aliphatic group that does not include a fluorine atom and may be the same as or different from one another, R⁶, R⁷, and R⁸ may form a ring structure with a carbon atom that is bonded thereto, and R⁹ and R¹⁰ are each a hydrogen atom or an unsubstituted alkyl group and may be the same as or different from each other; and
a monomer unit (III) represented by formula (III), shown below: 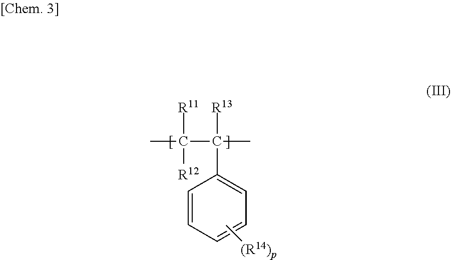
where, in formula (III), R¹¹ and R¹² are each a hydrogen atom or an unsubstituted alkyl group and may be the same as or different from each other, R¹³ is an optionally substituted alkyl group, R¹⁴ is a halogen atom or an organic group, and p is an integer of not less than 0 and not more than 5.

2. The copolymer according to claim 1, wherein R² is a group represented by L-Ar, where L is a fluorine atom-containing divalent linking group, and Ar is an optionally substituted aromatic ring group.

3. The copolymer according to claim 1, wherein R⁶, R⁷, and R⁸ are each a hydrogen atom or an optionally substituted aliphatic group having a carbon number of not less than 1 and not more than 10 that does not include a fluorine atom.

4. The copolymer according to claim 1, wherein a proportion constituted by the monomer unit (II) is less than 30 mol %.

5. A positive resist composition comprising: the copolymer according to claim 1; and a solvent.

6. A method of forming a resist pattern comprising:
forming a resist film using the positive resist composition according to claim 5;
exposing the resist film; and
developing the resist film that has been exposed.

7. The method of forming a resist pattern according to claim 6, wherein the developing is performed using an alcohol solvent.
